(19) United States
(12) Patent Application Publication
(10) Pub. No.: US 2025/0275463 A1
(43) Pub. Date: Aug. 28, 2025

(54) TETRADENTATE PLATINUM COMPLEX LIGHT-EMITTING MATERIAL BASED ON TETRAARYLETHYLENE SKELETON STRUCTURE AND USE THEREOF

(71) Applicant: GUANGDONG AGLAIA OPTOELECTRONIC MATERIALS CO., LTD, Foshan, Guangdong (CN)

(72) Inventors: Huiyang LI, Foshan, Guangdong (CN); Xinwei WU, Foshan, Guangdong (CN); Haijian TAN, Foshan, Guangdong (CN); Lei DAI, Foshan, Guangdong (CN); Lifei CAI, Foshan, Guangdong (CN)

(73) Assignee: GUANGDONG AGLAIA OPTOELECTRONIC MATERIALS CO., LTD, Foshan, Guangdong (CN)

(21) Appl. No.: 18/858,298

(22) PCT Filed: Apr. 14, 2023
(86) PCT No.: PCT/CN2023/088244

§ 371 Date: Oct. 18, 2024

(30) Foreign Application Priority Data
Apr. 25, 2022 (CN) 202210437829.2
Mar. 23, 2023 (CN) 202310294786.1

(51) Int. Cl. H10K 85/30; C07F 15/00; C09K 11/06; H10K 50/12

(52) U.S. Cl. CPC H10K 85/346; C07F 15/0086; C09K 11/06; C09K 2211/1007; C09K 2211/1029; C09K 2211/1044; C09K 2211/185; H10K 50/12

(57) ABSTRACT

The present disclosure relates to a tetradentate platinum complex light-emitting material based on a tetraarylethylene skeleton structure and use thereof. The platinum complex is a compound having a structure of chemical formula (I). Such material has the property of aggregation-induced emission, with a relatively high luminescence quantum yield and a short excited-state lifetime. Also provided is an organic electroluminescent photoelectric device, which includes a cathode, an anode and an organic layer. The organic layers are one or more of a hole injection layer, a hole transport layer, a light-emitting layer, a hole blocking layer, an electron transport layer and an electron injection layer. At least one of the organic layers contains the compound represented by structural formula (I).

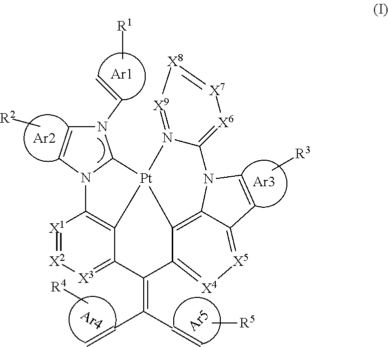

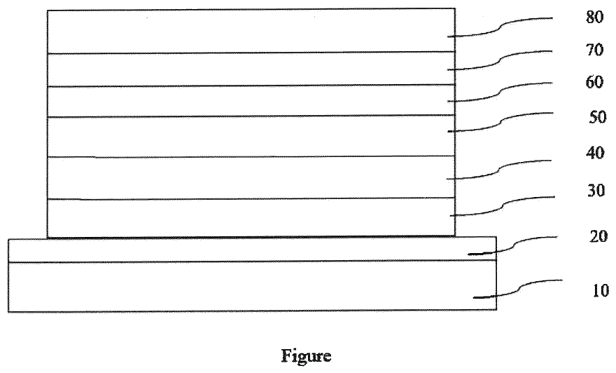

### CROSS-REFERENCE TO RELATED APPLICATIONS

The present application is a national phase entry under 35 USC § 371 of International Application No. PCT/CN2023/088244 filed Apr. 14, 2023, which claims the benefit of and priority to Chinese Patent Application No. 202210437829.2, filed Apr. 25, 2022, and Chinese Patent Application No. 202310294786.1, filed Mar. 23, 2023, the entire disclosures of which are incorporated herein by reference.

### TECHNICAL FIELD

The present disclosure relates to the field of metal complex light-emitting materials, and in particular, to a tetradentate platinum complex based on a tetraarylethylene skeleton structure and use thereof in organic light-emitting diodes.

### BACKGROUND

Organic light-emitting diode (OLED) has many advantages such as self-luminescence, short response time, wide operating temperature range and high flexibility, and therefore they have broad application prospects in a new generation of flat panel displays, solid-state lighting, and flexible displays, and has become one of the focuses of competition in high-tech fields of various countries. However, the existing OLED still has the problem of short device life, and the luminous efficiency thereof needs to be further improved.

The performance of OLED devices depends largely on the light-emitting materials used. Early fluorescent OLED may usually only use singlet-state excitons to emit light, and the triplet-state excitons generated in the devices cannot emit light and return to the ground state through non-radiation methods, which hinders the improvement of OLED efficiency. In 1998, Professor Zhiming ZHI of the University of Hong Kong and his collaborators used transition metal complexes to achieve triplet-state luminescence, effectively improving exciton utilization rate. In the same year, Thompson et al. also reported the electrophosphorescence phenomenon of transition metal complexes. Phosphorescent OLED may effectively utilize triplet-state and singlet-state excitons and can theoretically achieve 100% internal quantum efficiency, which promotes the commercialization process of OLED. The control of OLED emitting color may be achieved through the structural design of the light-emitting materials. OLED may include one light-emitting layer or multiple light-emitting layers to achieve the desired spectrum. Green, yellow and red phosphorescent materials have been commercialized. Commercial OLED displays usually use blue fluorescence and yellow, or green and red phosphorescence to achieve full-color display. The light-emitting materials with higher efficiency and longer service life are urgently needed by the current industry.

Compared with red and green light-emitting materials, the research on blue phosphorescent materials is relatively lagging behind. The types and quantities of related materials are relatively small, which has become the main factor hindering their development. The development of efficient and stable blue phosphorescent materials is of great significance for further promoting the industrial application of blue phosphorescent OLED device.

### SUMMARY

For the above problems, the present disclosure provides a tetradentate platinum complex light-emitting material based on a tetraarylethylene skeleton structure. Such material is applied to organic light-emitting diodes and exhibit good light-emitting efficiency and device life.

The present disclosure also provides an organic light-emitting diode based on the platinum complex.

A tetradentate platinum complex is a compound with a structure of formula (I):

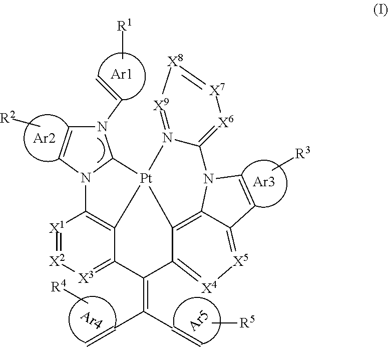

wherein:
X¹-X⁹ are independently selected from N or CR⁶;
R¹ to R⁶ are independently selected from hydrogen, deuterium, amine, halogen, carbonyl group, carboxyl group, cyano group, phosphino, substituted or unsubstituted alkyl group with 1-20 carbon atoms, substituted or unsubstituted cycloalkyl group with 3-20 ring carbon atoms, substituted or unsubstituted alkenyl group with 2-20 carbon atoms, substituted or unsubstituted alkoxy group with 1-20 carbon atoms, substituted or unsubstituted aryl group with 6-30 carbon atoms, or substituted or unsubstituted heteroaryl group with 3-30 carbon atoms;
Ar¹ to Ar⁵ are five-membered aromatic rings, six-membered aromatic rings, five-membered heteroaromatic rings or six-membered heteroaromatic rings;
a heteroatom in the heteroaryl group or the heteroaromatic ring are one or more of N, O and S;
a substitution is conducted by halogen, amine, cyano group or C1-C4 alkyl group.

In an embodiment, R¹ to R⁶ are each independently selected from hydrogen, deuterium, halogen, amine, cyano group, substituted or unsubstituted alkyl group with 1-6 carbon atoms, substituted or unsubstituted cycloalkyl group with 3-6 ring carbon atoms, substituted or unsubstituted alkenyl group with 2-6 carbon atoms, substituted or unsubstituted alkoxy group with 1-6 carbon atoms, substituted or unsubstituted aryl group with 6-12 carbon atoms, or substituted or unsubstituted of heteroaryl group with 3-6 carbon atoms.

In an embodiment, R¹ to R⁶ are each independently selected from hydrogen, deuterium, halogen, C1-C4 alkyl group, cyano group, substituted or unsubstituted cycloalkyl with 3-6 cyclic carbon atoms, substituted or unsubstituted aryl group having 6-12 carbon atoms, or substituted or unsubstituted heteroaryl group with 3-6 carbon atoms.

In an embodiment, R¹ to R⁶ are each independently selected from hydrogen, deuterium, fluorine, methyl, isopropyl, isobutyl, tert-butyl, cyano group, substituted or unsubstituted cyclopentyl, substituted or unsubstituted cyclohexyl, substituted or unsubstituted phenyl, substituted or unsubstituted pyridyl, substituted or unsubstituted pyrazinyl, or substituted or unsubstituted pyrimidinyl.

In an embodiment, the formula (I) has the following structures:

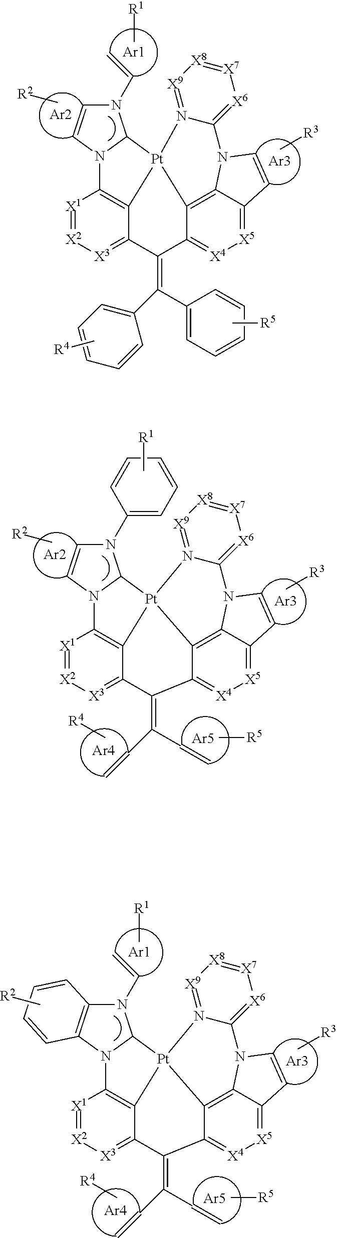

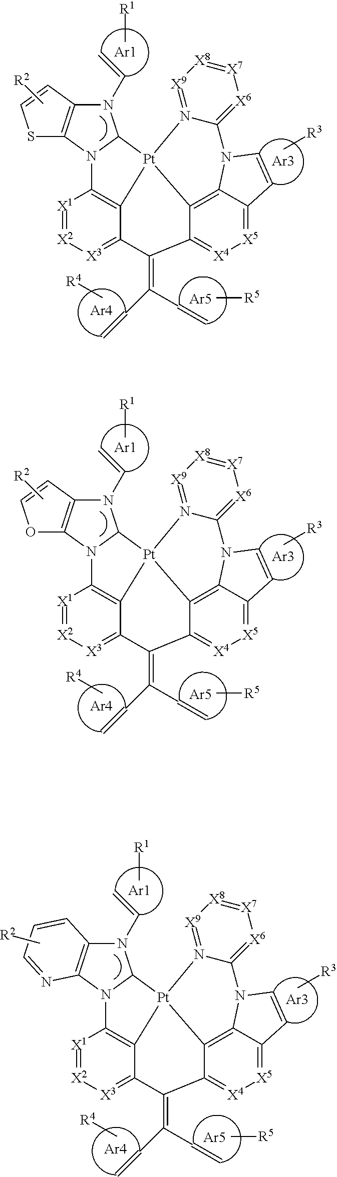

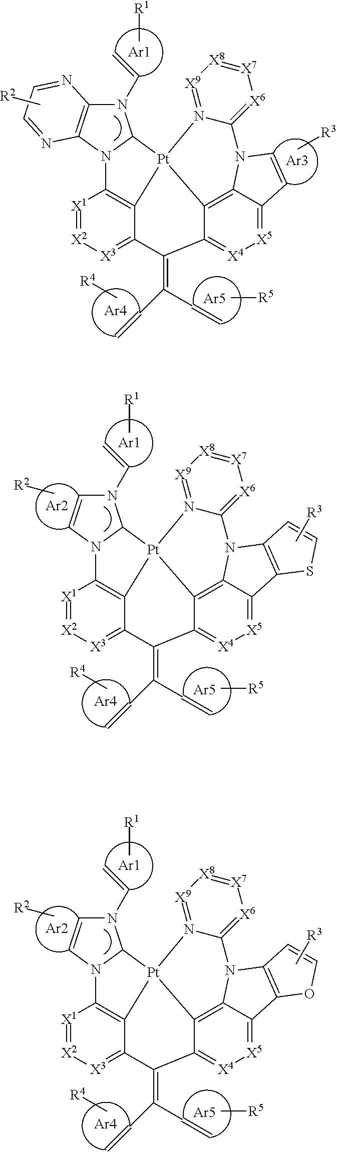

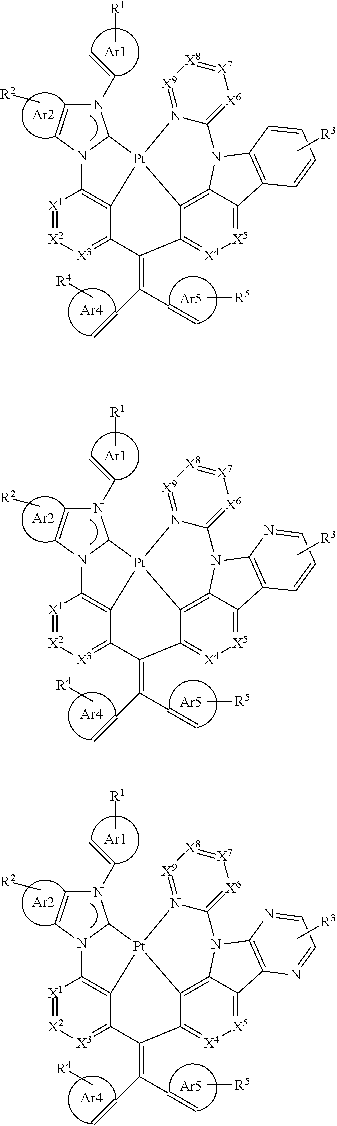

R¹ to R⁶ are each independently selected from hydrogen, deuterium, fluorine, methyl, tert-butyl, cyano group, substituted or unsubstituted cyclopentyl, substituted or unsubstituted cyclohexyl, or substituted or unsubstituted phenyl.
Ar¹, Ar⁴, and Ar⁵ are each independently selected from a five-membered aromatic ring, a six-membered aromatic ring, a five-membered heteroaromatic ring, and a six-membered heteroaromatic ring; Ar² and Ar³ are each independently selected from a six-membered aromatic ring or a six-membered heteroaromatic ring.

In an embodiment, the formula (I) has the following structures:

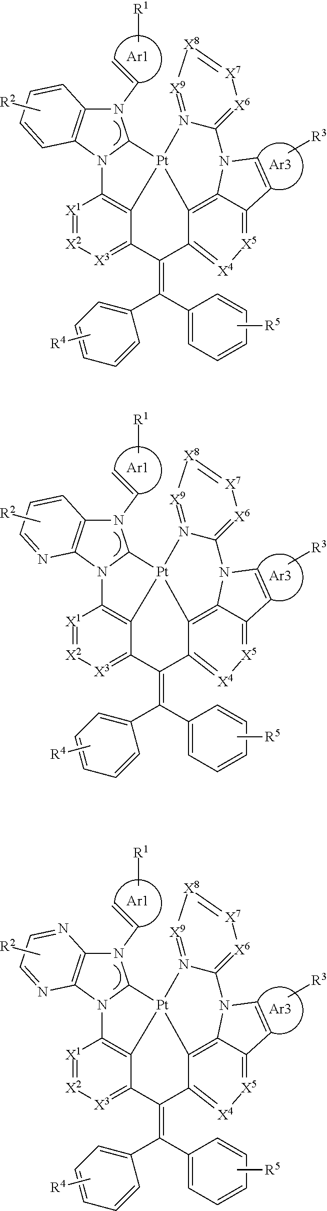

X¹-X³ and X⁶-X⁹ are independently selected from CR⁶; and X⁴-X⁵ are independently selected from N or CR⁶.

Ar¹, Ar⁴ and Ar⁵ are selected from phenyl or pyridyl, Ar² and Ar³ are each independently selected from a six-membered aromatic ring, and X¹-X³, X⁶-X⁹ and X⁴-X⁵ are independently selected from CR⁶.

R¹ to R⁶ are each independently selected from hydrogen, deuterium, fluorine, or tert-butyl.

Examples of platinum metal complexes according to the present disclosure are listed below, but not limited to the listed structures:

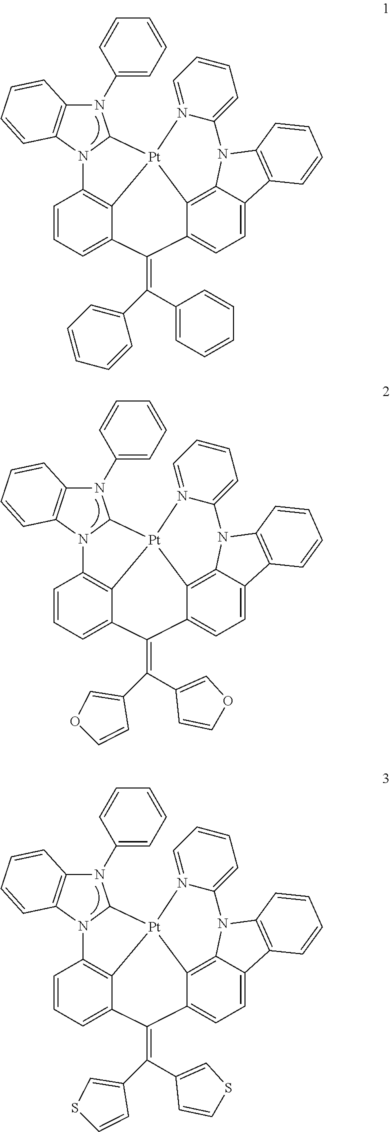

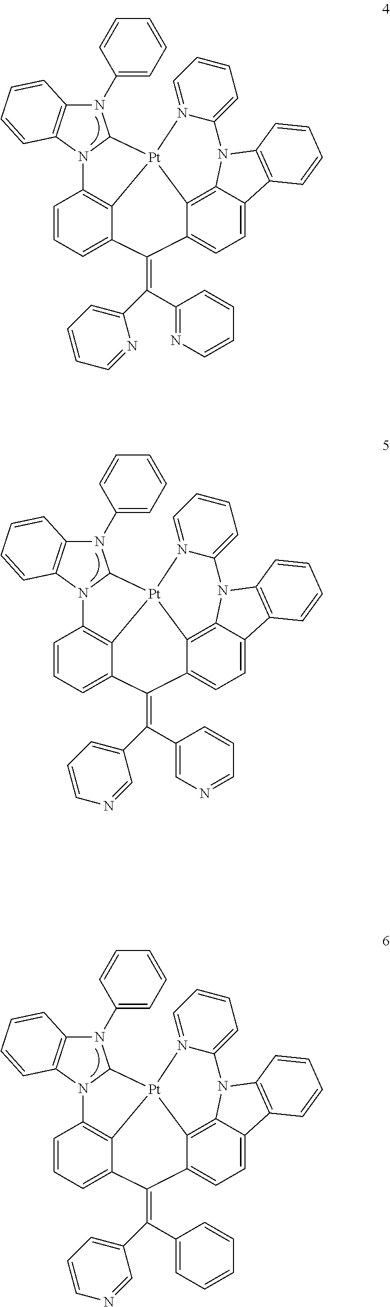

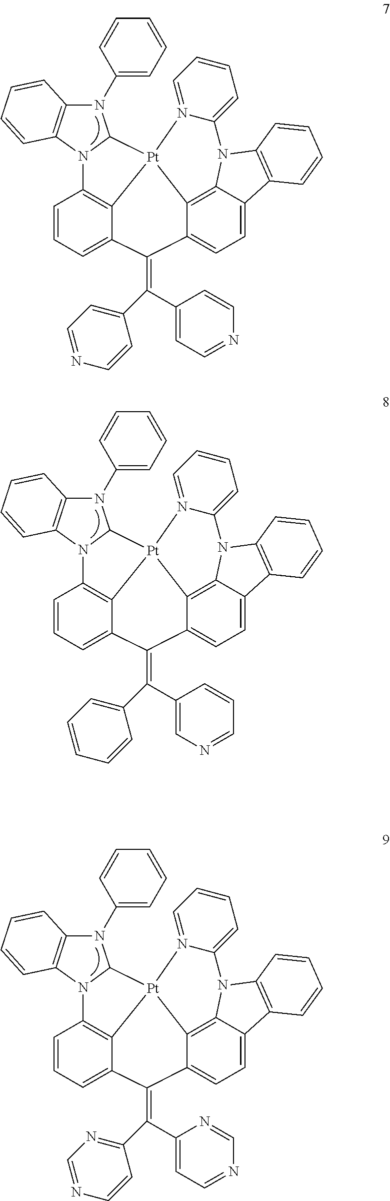

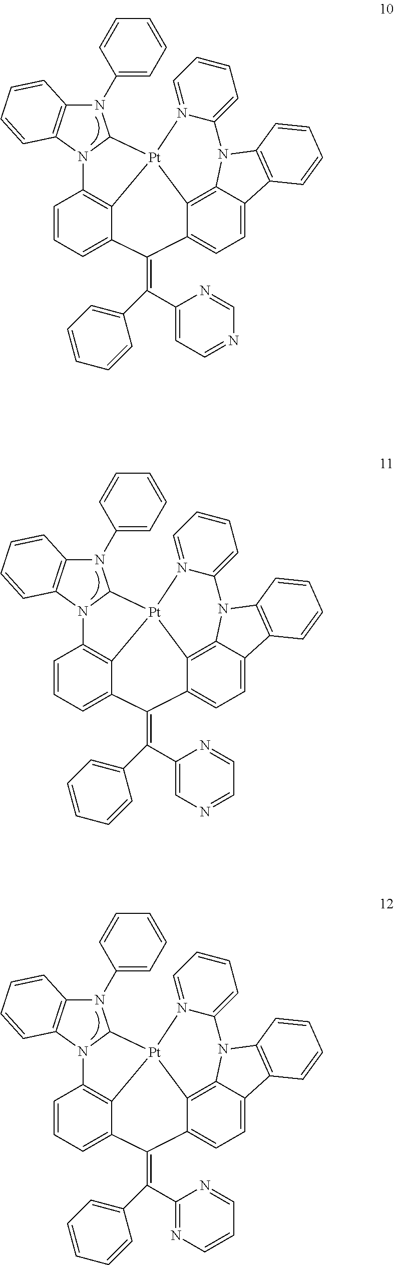

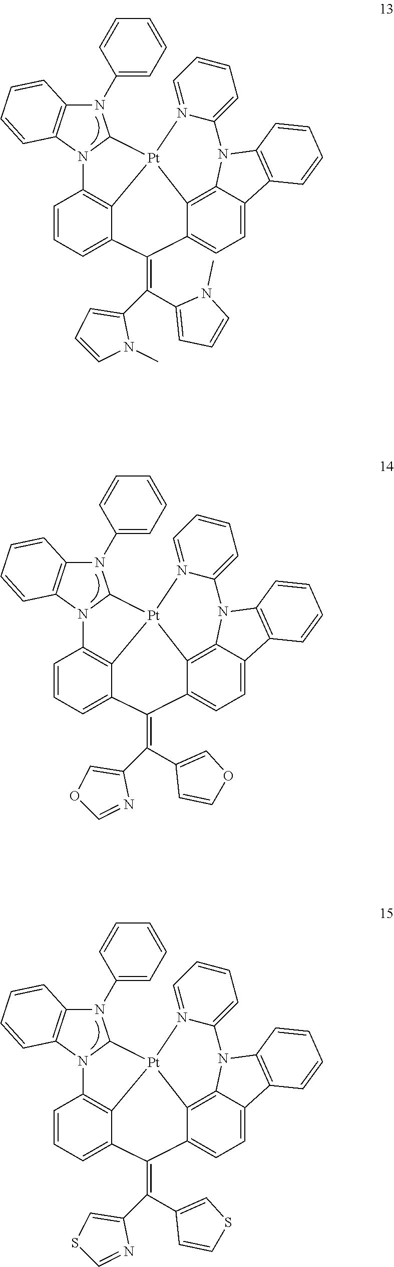

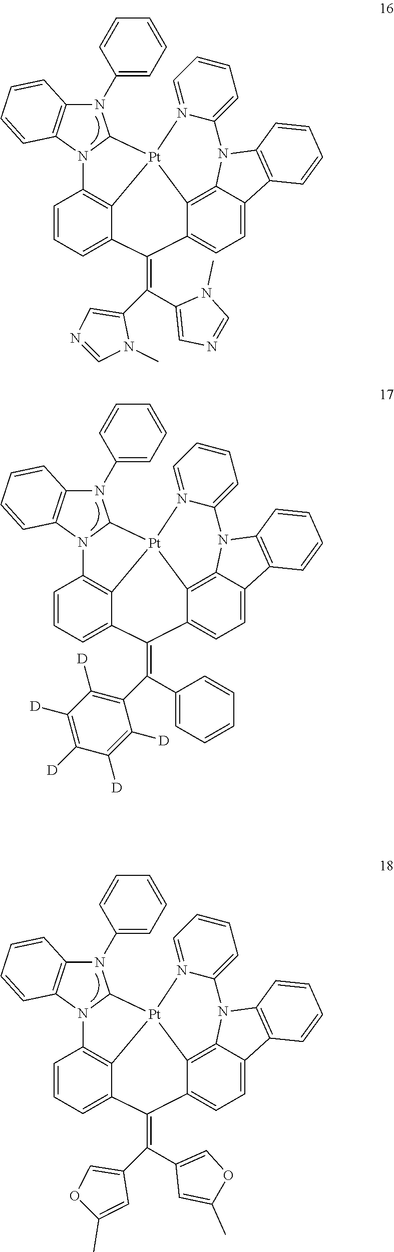

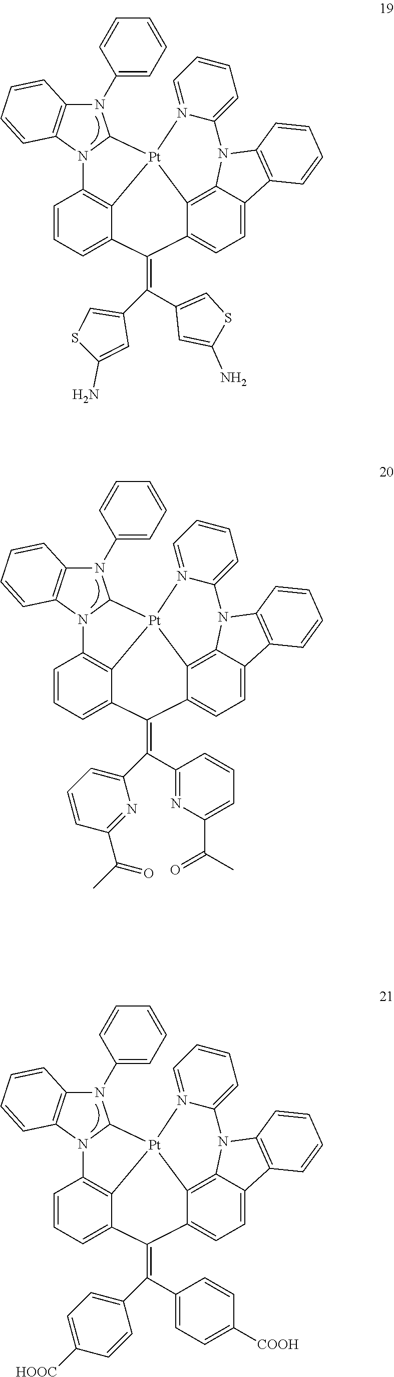

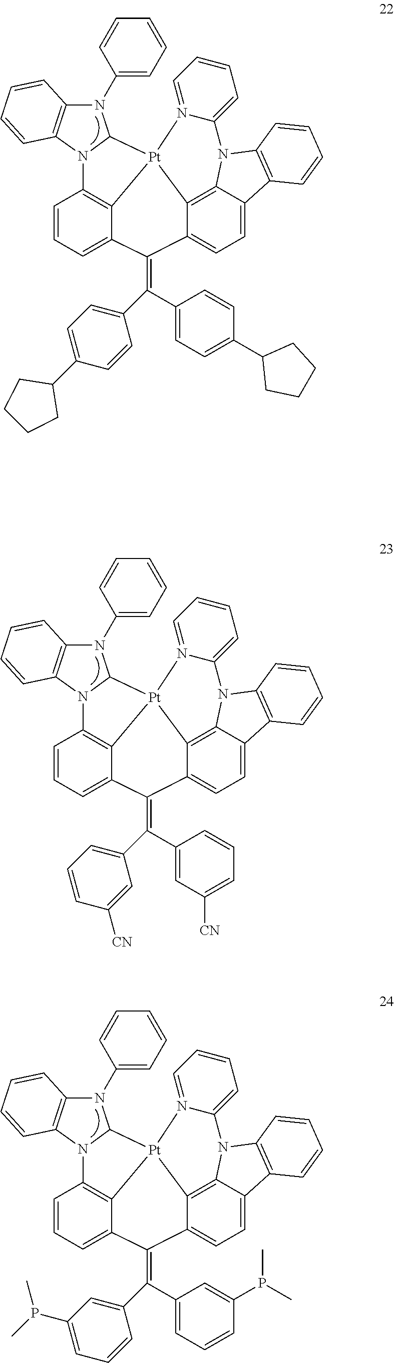

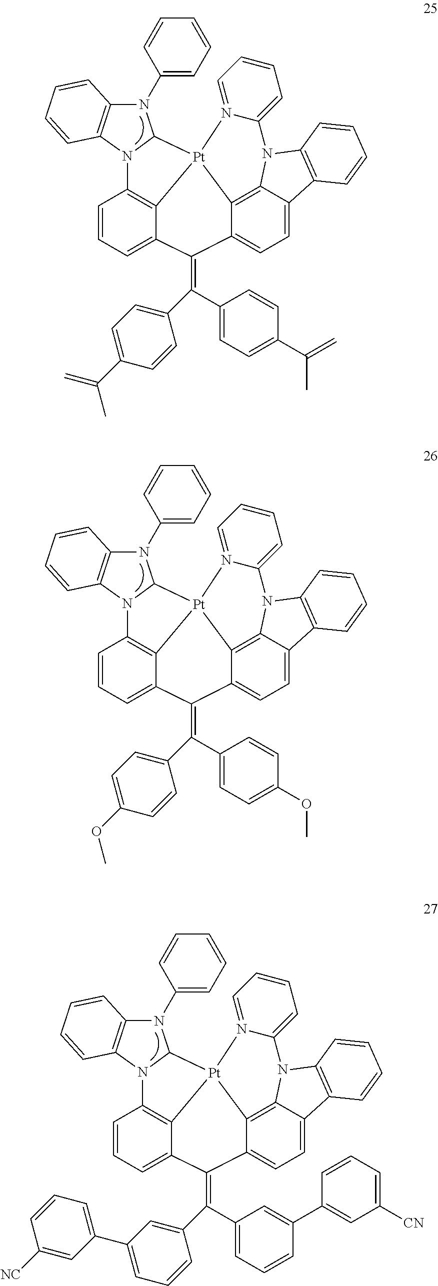

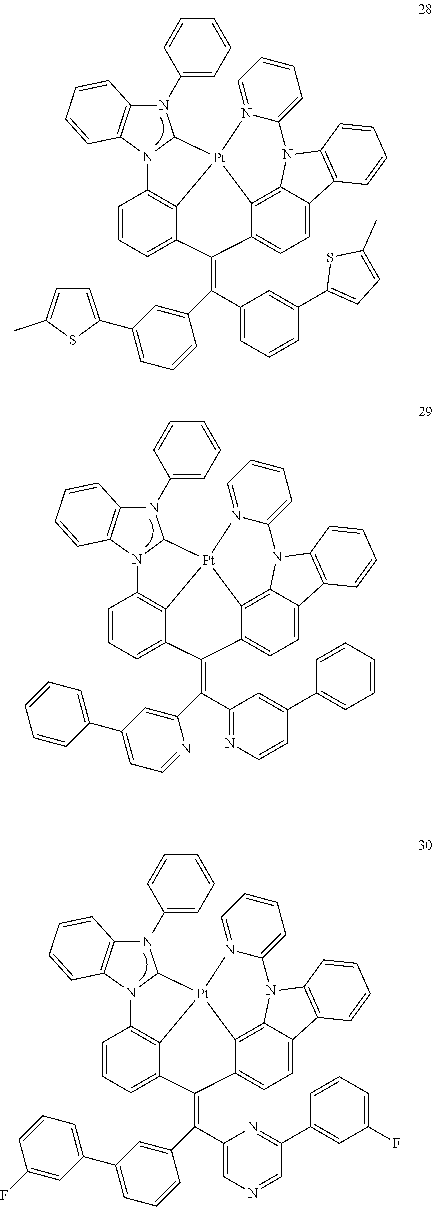

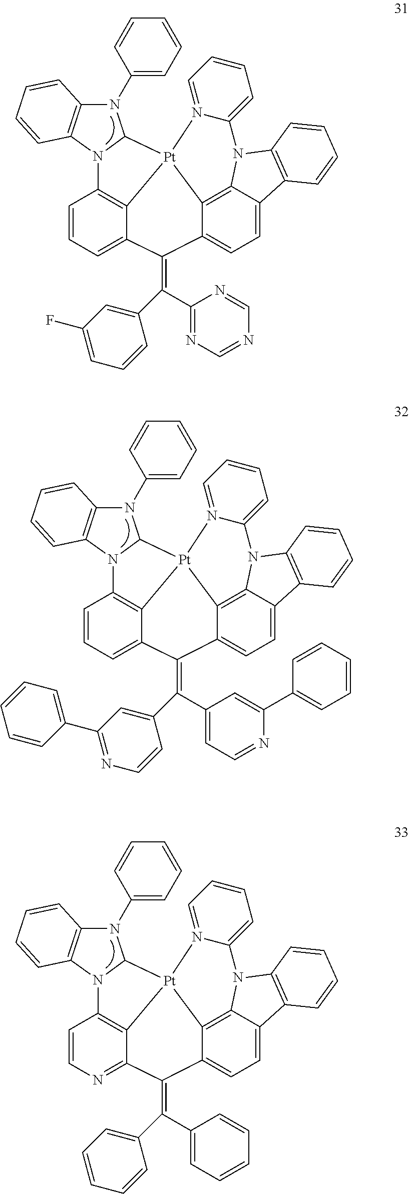

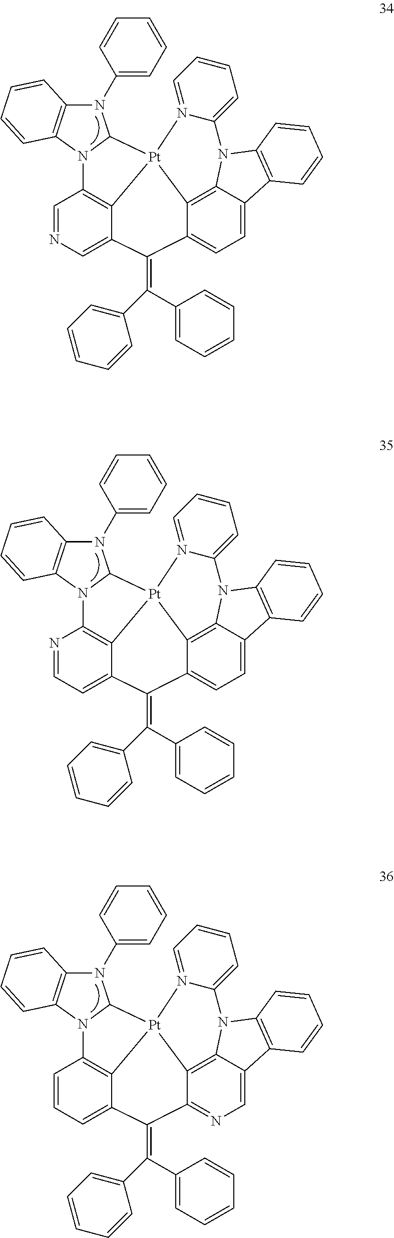

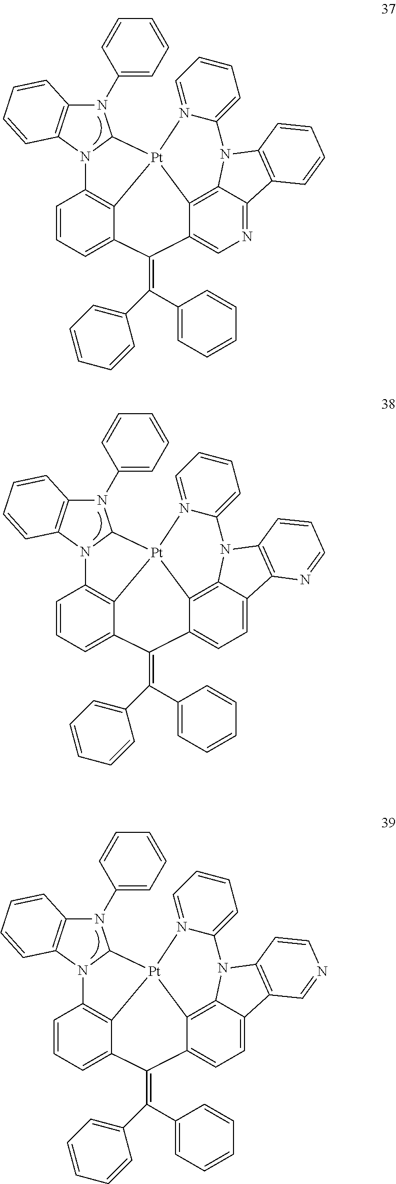

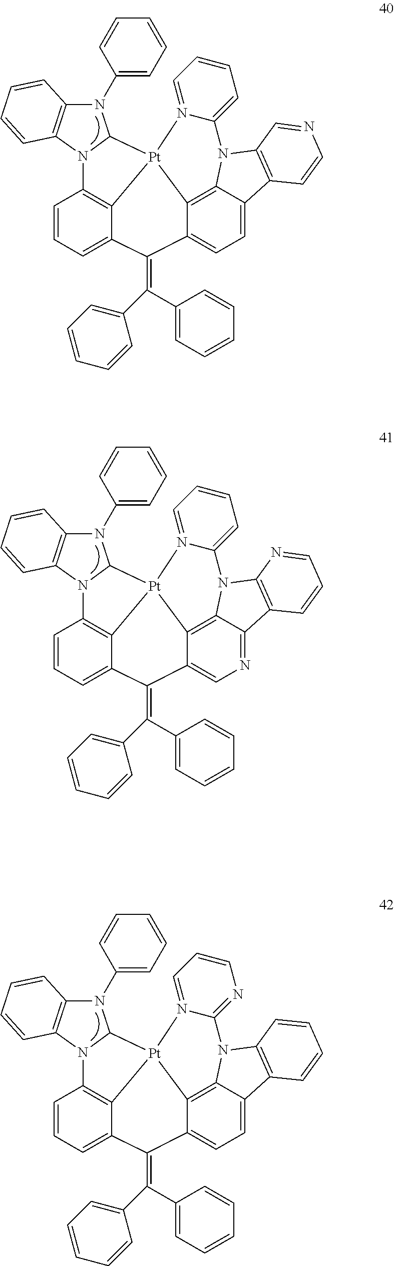

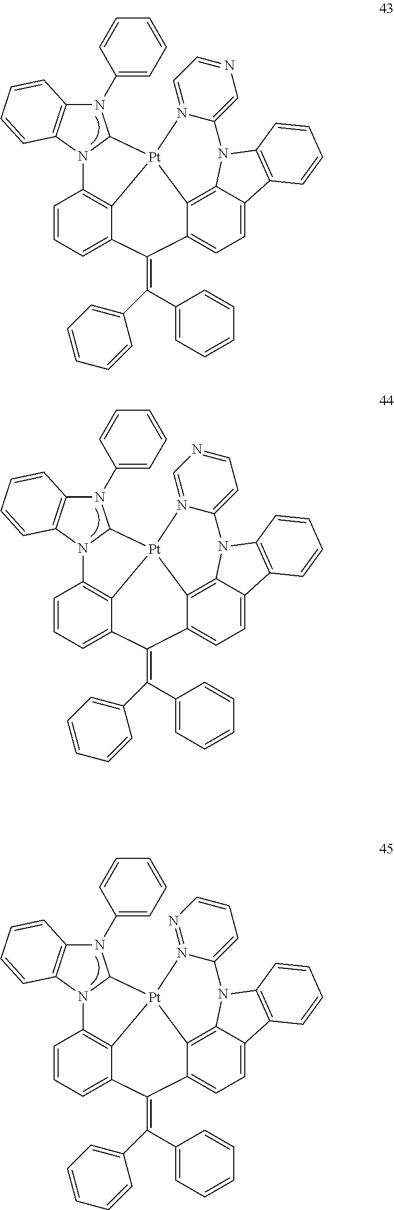

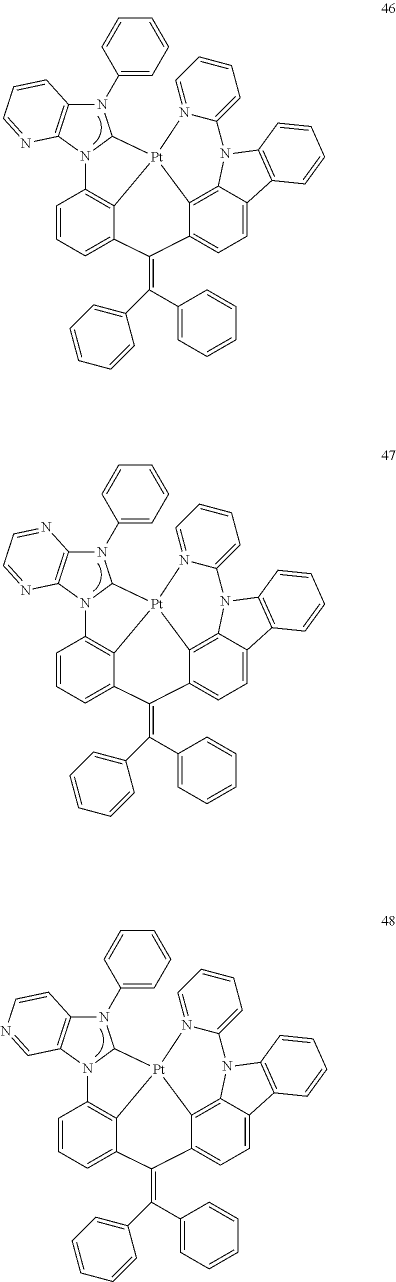

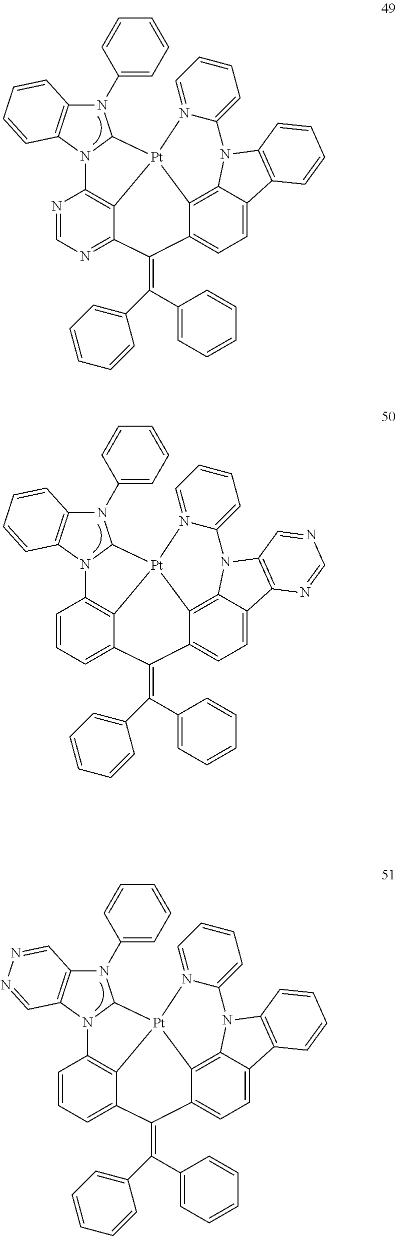

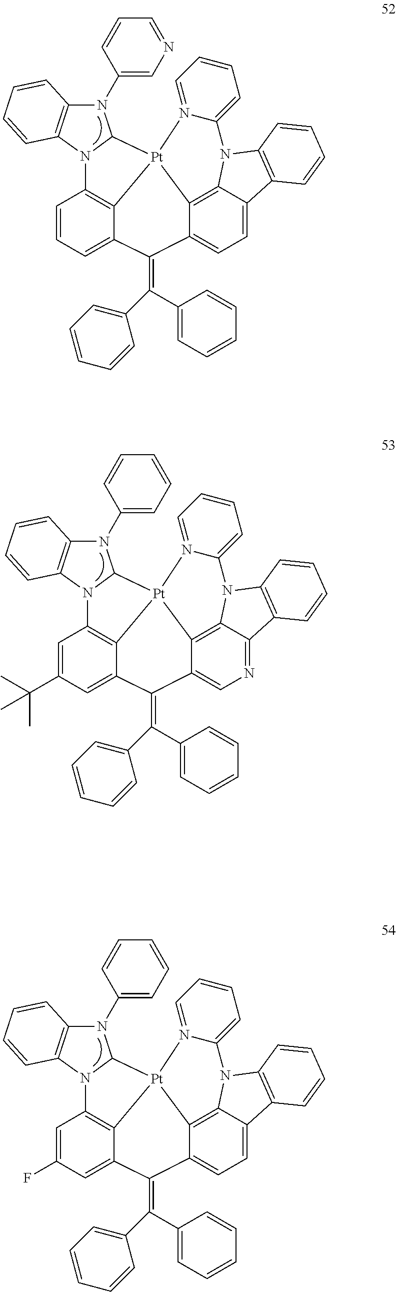

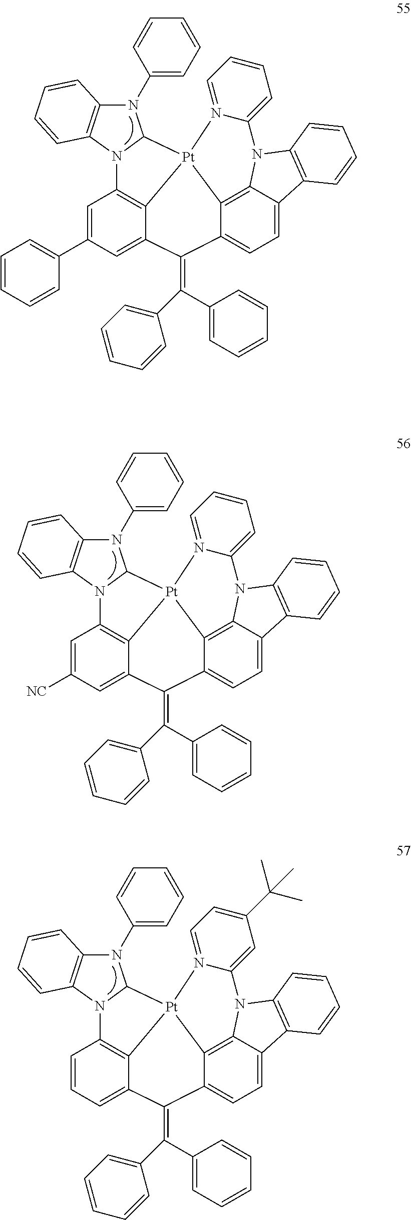

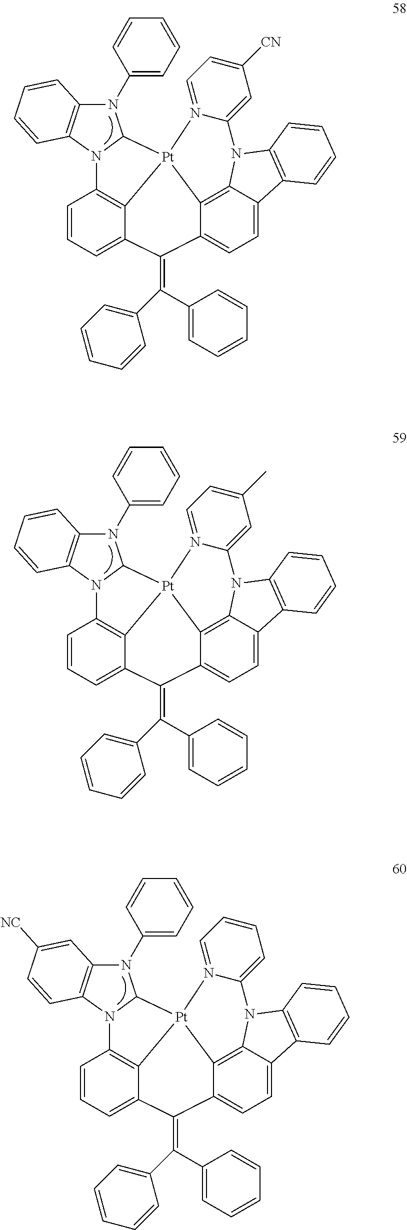

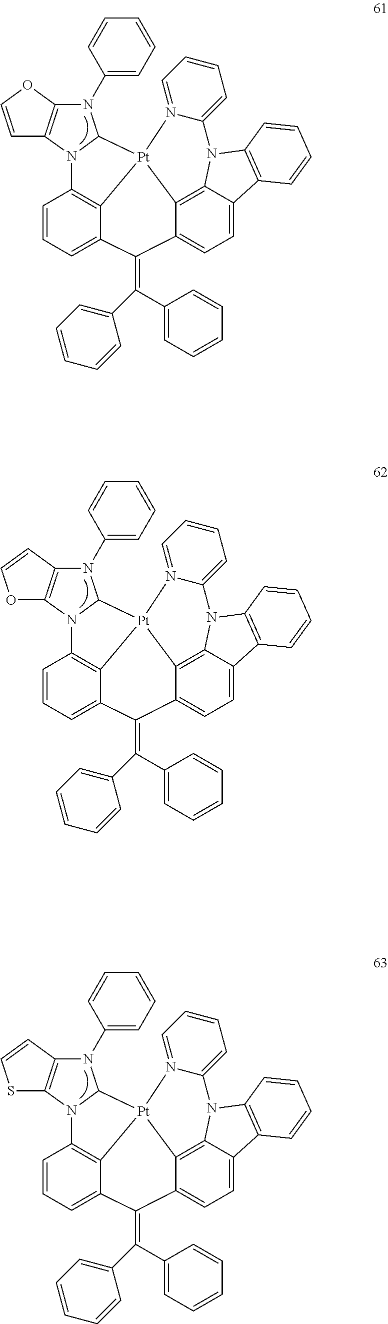

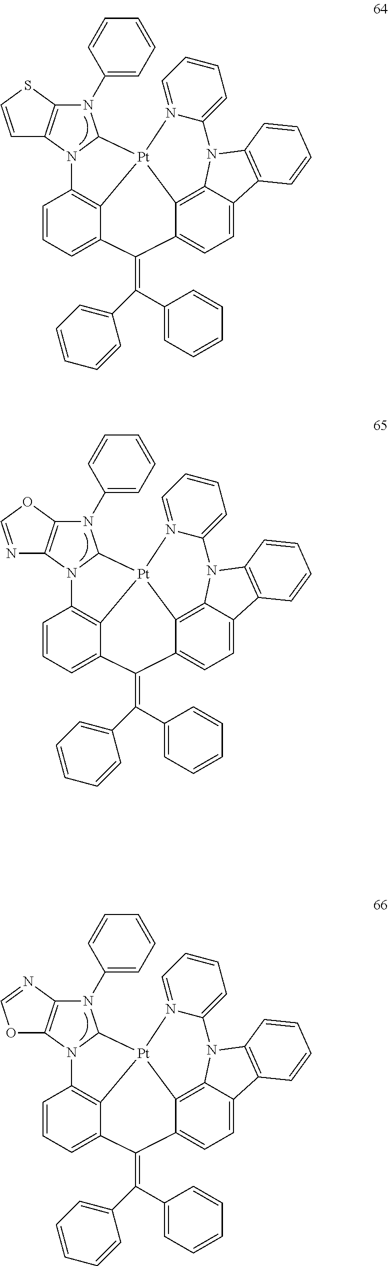

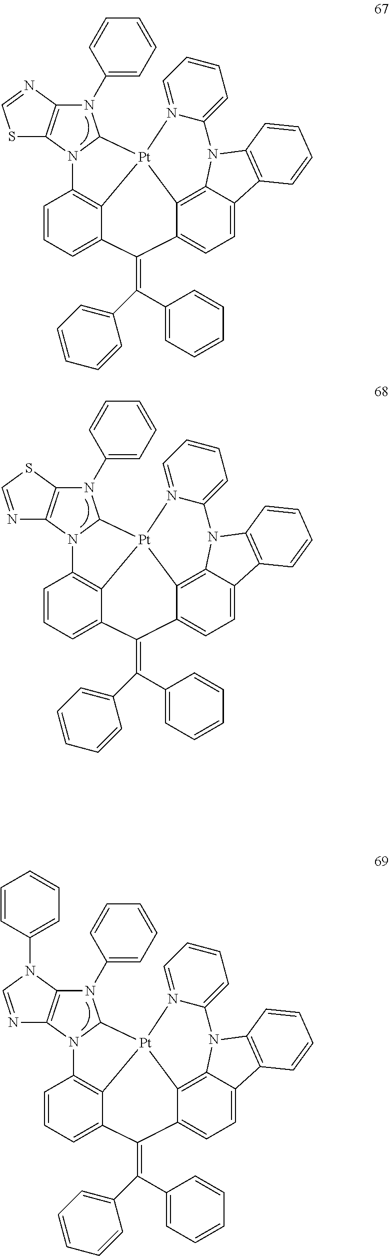

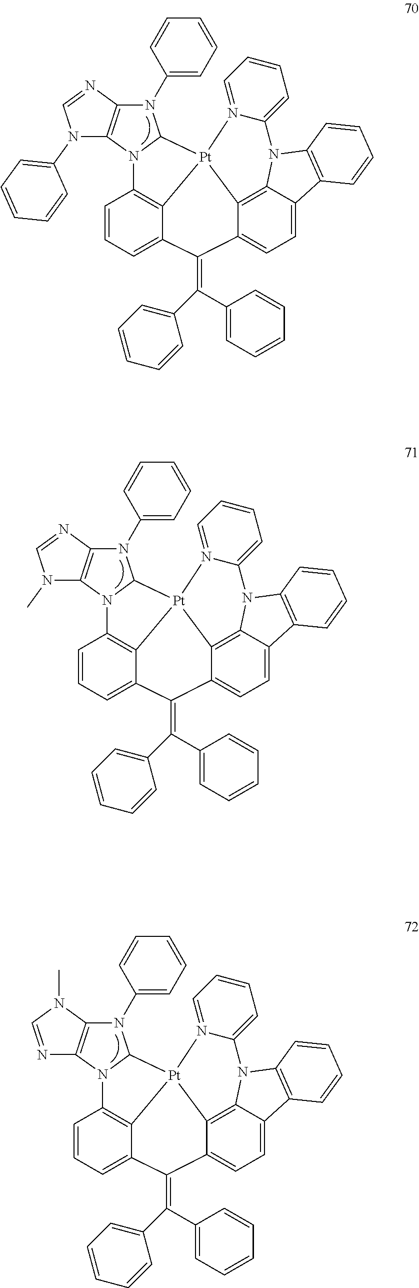

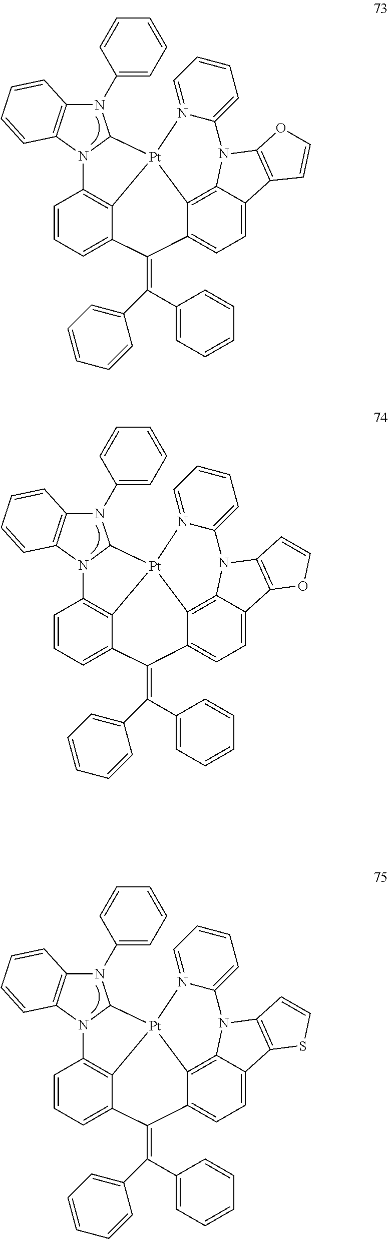

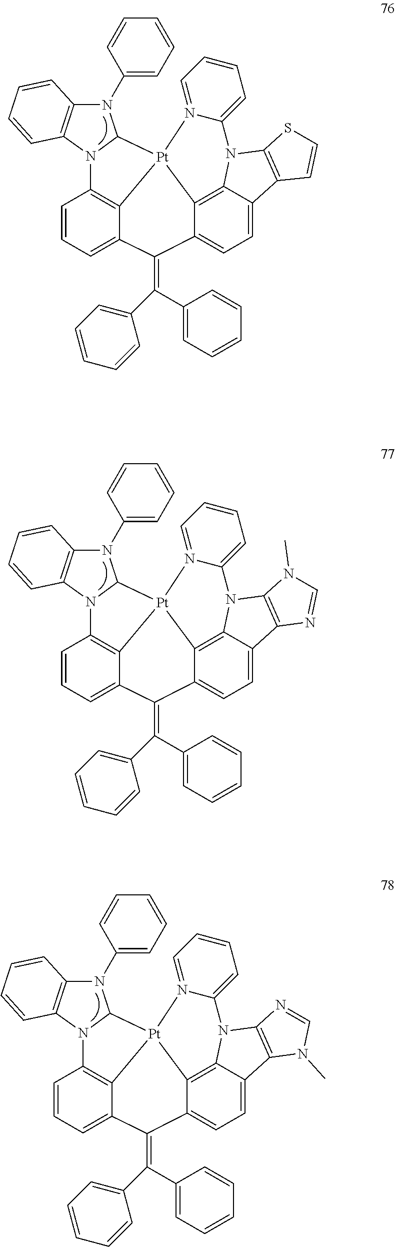

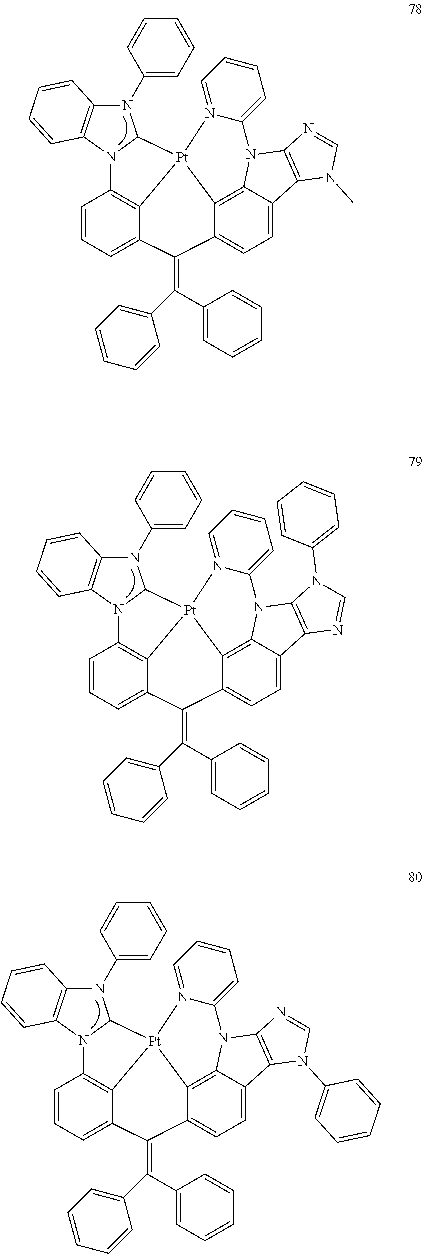

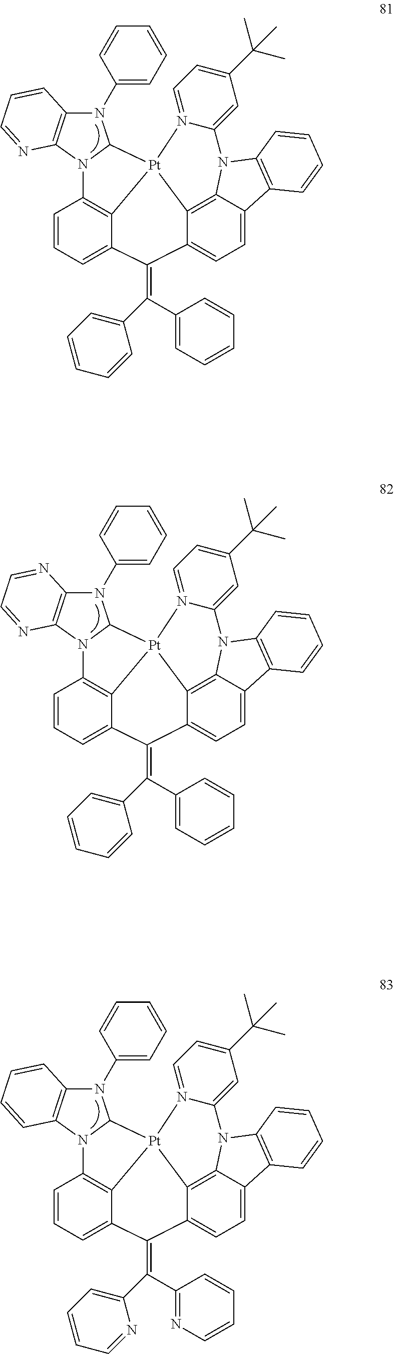

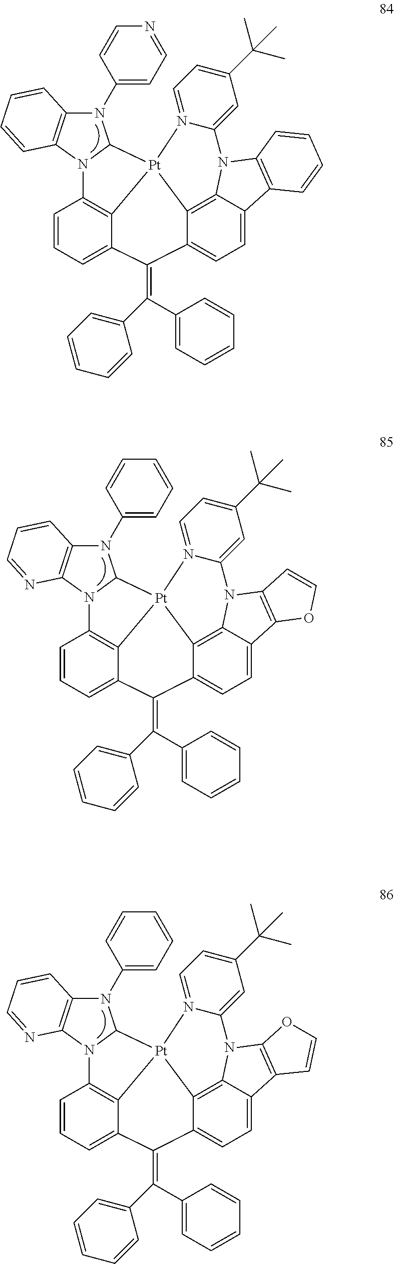

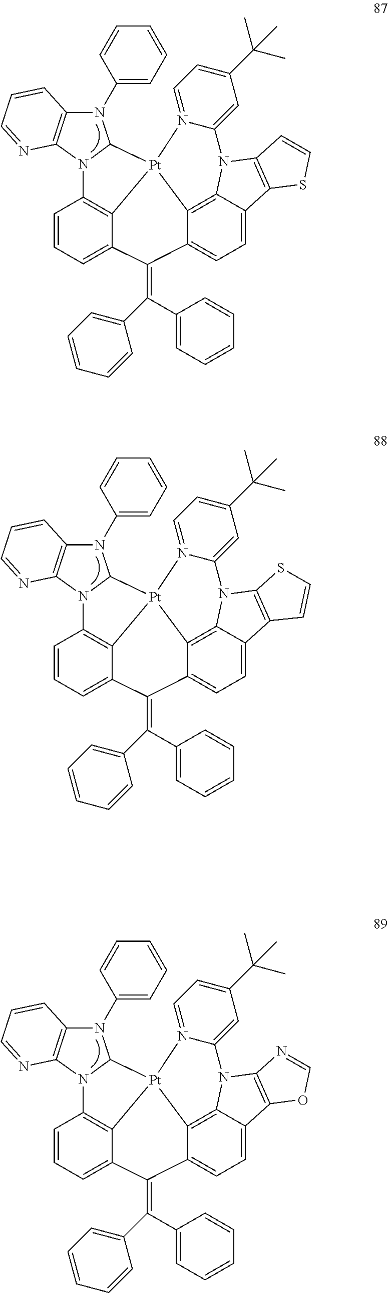

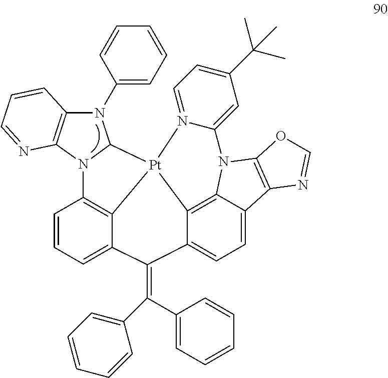

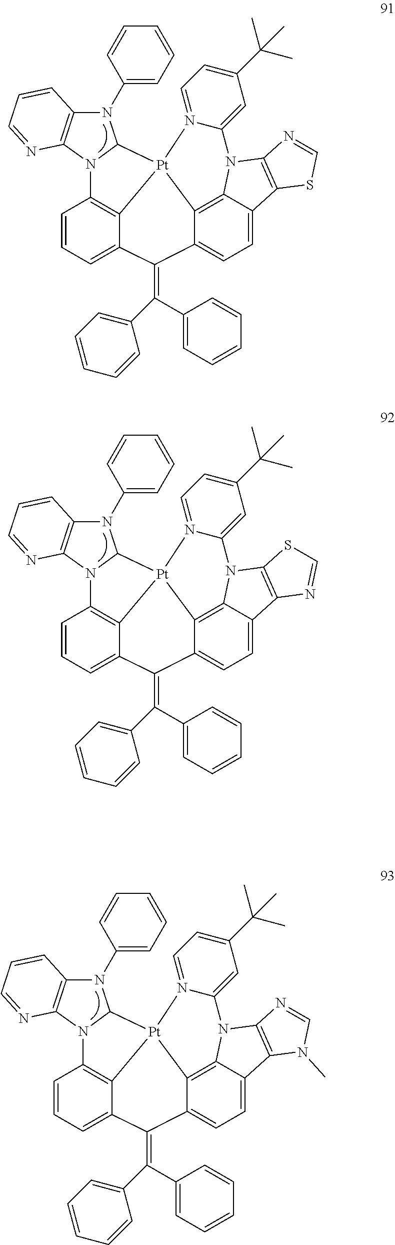

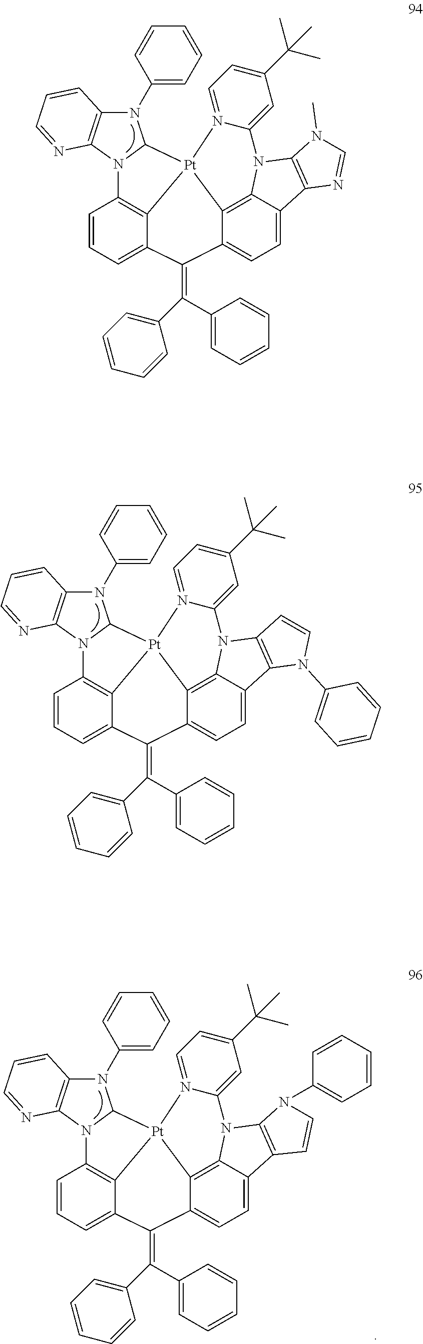

The above metal complex has a precursor structural formula of:

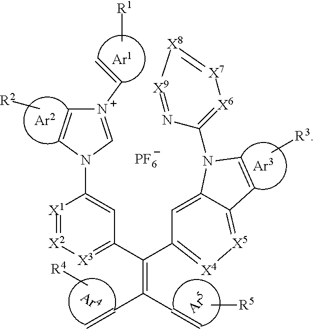

The present disclosure further provides use of the above-mentioned platinum complex in organic optoelectronic devices. The optoelectronic devices include, but not limited to, organic light emitting diode (OLED), organic thin film transistor (OTFT), organic photovoltaic device (OPV), light-emitting electrochemical cell (LEC) and chemical sensor, such as OLED.

An organic light-emitting diode (OLED) containing the above-mentioned platinum complex, wherein the platinum complex is a light-emitting material in a light-emitting device.

The organic light-emitting diode in the present disclosure includes a cathode, an anode and an organic layer. The organic layer is one or more of a hole injection layer, a hole transport layer, a light-emitting layer, a hole blocking layer, an electron injection layer and an electron transport layer. These organic layers need not be present in every layer; at least one layer of the hole injection layer, hole transport layer, hole blocking layer, electron injection layer, light-emitting layer and electron transport layer contains the platinum complex represented by formula (I).

In an embodiment, the layer in which the platinum complex described in formula (I) is located is the light-emitting layer or the electron transport layer.

The total thickness of the organic layer of the device of the present disclosure is 1-1000 nm, such as 1-500 nm, such as 5-300 nm.

The organic layer may be formed into a thin film by distillation or a solution method.

The present disclosure discloses a series of tetradentate platinum complex light-emitting materials based on a tetraaryl skeleton structure, which have the property of aggregation-induced emission, can effectively improve the purity of the light-emitting color, and have a short excited state lifetime, thereby improving the luminous efficiency and device stability.

### BRIEF DESCRIPTION OF DRAWINGS

FIGURE is a structural diagram of an organic light-emitting diode device of the present disclosure.

In which, 10 represents a glass substrate, 20 represents an anode, 30 represents a hole injection layer, 40 represents a hole transport layer, 50 represents a light-emitting layer, 60 represents an electron transport layer, 70 represents an electron injection layer, and 80 represents a cathode.

### DETAILED DESCRIPTION

The present disclosure will be further described in detail below with reference to examples.

The raw materials used in the examples are all commercially available products.

### Example 1: Preparation of Complex 57

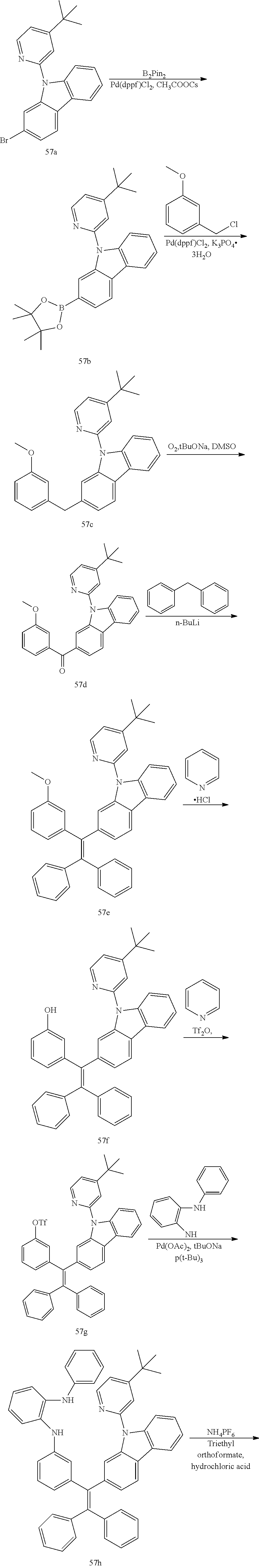

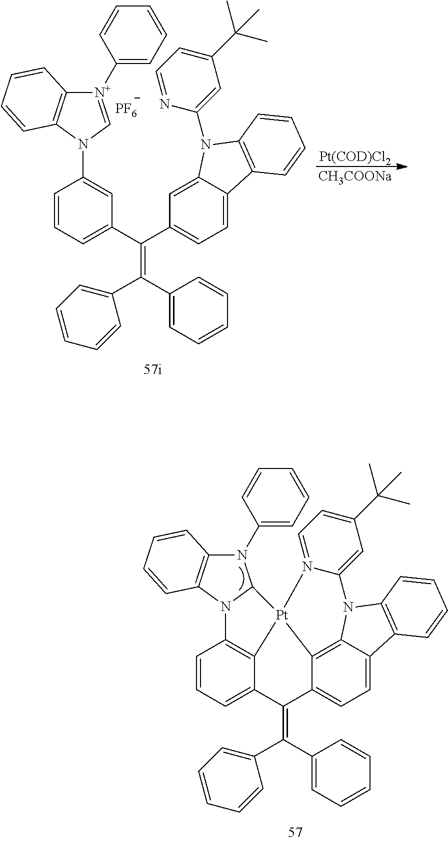

### Synthesis of Compound 57b

A 2 L single-necked bottle was taken and successively added with 57a (67 g, 177.2 mmol, see Organometallics, 2021, 40, 472-481: Synthesis), B₂Pin₂ (67.5 g. 265.9 mmol), Pd (dppf) Cl₂ (6.5 g, 8.9 mmol), cesium acetate (68 g, 354.4 mmol) and toluene (670 mL) for reaction under nitrogen protection at 110° C. for 24 h. After the reaction was completed, suction filtration was performed, and a resulting filtrate was spin-dried at 60° C. and subjected to silica gel column chromatography to obtain 58 g of a white solid with a yield rate of 76.8%. HRMS (ESI) (m/z): 427.2550 [M+H]⁺.

### Synthesis of Compound 57c

A 2 L single-necked bottle was taken and successively added with 57b (58 g, 136.1 mmol), 3-methoxybenzyl chloride (31.8 g, 204.2 mmol), Pd (dppf) Cl₂ (4.9 g, 6.8 mmol), K₃PO₄·3H₂O (108.2 g, 408.3 mmol) and toluene/ethanol/water (200/200/100 mL) for reaction under nitrogen protection at 100° C. for 16 h. After the reaction was completed, suction filtration was performed, and a resulting filtrate was spin-dried and subjected to silica gel column chromatography to obtain 50 g of light yellow oil with a yield rate of 87.4%. HRMS (ESI) (m/=): 421.2214 [M+H]⁺.

### Synthesis of Compound 57d

A 1 L single-necked bottle was taken and successively added with 57c (50 g, 119 mmol), tBuONa (22.8 g, 238 mmol) and DMSO (500 mL) for reaction under oxygen atmosphere at 50° C. for 16 h. After the reaction was completed, 2 L of water were added to achieve a solution with a pH adjusted to 6-7, and then the solution was extracted with ethyl acetate (500 mL*3). An organic phase was spin-dried and subjected to silica gel column chromatography to obtain 38.6 g of a white solid with a yield rate of 74.8%. HRMS (ESI) (m/=): 435.1985 [M+H]⁺.

### Synthesis of Compound 57e

Under nitrogen protection, diphenylmethane (11.6 g, 69.0 mmol) was dissolved in tetrahydrofuran (150 mL) to achieve a solution. At −78° C., n-butyllithium (2M, 40 mL) was added dropwise to the above solution, stirred for 1 h, then heated to −40° C. for further reaction for 0.5 h. Compound 57d (20.0 g, 46.0 mmol) and tetrahydrofuran (100 mL) were added dropwise to the above solution, and continued to react for 15 h. After the reaction was completed, 500 mL of water were added thereto. The resulting solution was extracted with ethyl acetate (200 mL*3). The organic phase was removed by vacuum distillation under reduced pressure, and the resulting residue was subjected to silica gel column chromatography to obtain 19.2 g of light yellow solid with a yield rate of 71.3%. HRMS (ESI) (m/=): 585.2921 [M+H]⁺.

### Synthesis of Compound 57f

Under nitrogen protection, a mixture of compound 57e (19.0 g, 32.5 mmol) and pyridine hydrochloride (100 g) was heated to 190° C. for 6 h, and cooled to room temperature to achieve a solution, into which 500 mL of water were added, and the solution was extracted with ethyl acetate (200 mL*3). The organic phase was removed by vacuum distillation under reduced pressure, and the resulting residue was subjected to silica gel column chromatography to obtain 17.9 g of light yellow solid with a yield rate of 96.5%. HRMS (ESI) (m/=): 571.2781 [M+H]⁺.

### Synthesis of Compound 57g

A 250 mL three-necked bottle was taken and added with 57f (12.6 g, 22.1 mmol), pyridine (3.49 g, 44.2 mmol) and dichloromethane (150 mL), into which trifluoromethanesulfonic anhydride (9.34 g, 33.1 mmol) was added dropwise in an ice bath under nitrogen protection. The resulting solution was heated to room temperature naturally and stirred overnight. After the reaction was completed, water (100 mL) was added to the solution, and the solution was extracted with dichloromethane (100 mL*3). The organic phase was removed by vacuum distillation under reduced pressure, and the resulting residue was subjected to silica gel column chromatography to obtain 9.6 g of light yellow solid with a yield rate of 61.9%. HRMS (ESI) (m/=): 703.2200 [M+H]⁺.

### Synthesis of Compound 57h

Under nitrogen protection, a mixture of 57 g (6.70 g, 9.53 mmol), sodium tert-butoxide (1.83 g, 19.1 mmol), N-phenyl-o-phenylenediamine (2.1 g, 11.4 mmol), palladium acetate (0.21 g, 0.95 mmol), tri-tert-butylphosphine (0.23 g, 1.14 mmol) and toluene (100 mL) was heated to 120° C. for 16 h to achieve a solution. After the reaction was completed, water (100 mL) was added to the solution, and the solution was extracted with dichloromethane (100 mL*3). The organic phase was removed by vacuum distillation under reduced pressure, and the resulting residue was subjected to silica gel column chromatography to obtain 5.4 g of light yellow solid with a yield rate of 76.9%. HRMS (ESI) (m/=): 737.3660 [M+H]⁺.

### Synthesis of Compound 57i

Under nitrogen protection, a mixture of compound 57h (2.1 g, 2.85 mmol), triethyl orthoformate (20 mL), ammonium hexafluorophosphate (2.79 g, 17.1 mmol) and acid salt (0.2 mL) was heated to 80° C. for reaction and stirred for 24 h, and 1.9 g of product was obtained by filtration. HRMS (ESI) (m/=): 747.3500 [M-PF6]⁺.

### Synthesis of Complex 57

Under nitrogen protection, a mixture of compound 57i (900 mg, 1.01 mmol), Pt(COD)Cl₂ (358 mg, 1.21 mmol) and sodium acetate (165 mg, 2.02 mmol) was added to the tetrahydrofuran solution (20 mL) and reacted at 120° C. for 24 h. After the reaction was completed, water (100 mL) was added thereto. The resulting solution was extracted with dichloromethane (100 mL*3). The organic phase was removed by vacuum distillation under reduced pressure, and the resulting residue was subjected to silica gel column chromatography to obtain 0.32 g of light yellow solid with a yield rate of 33.7%. HRMS (ESI) (m/=): 940.2985 [M+H]⁺.

### Example 2: Preparation of Complex 83

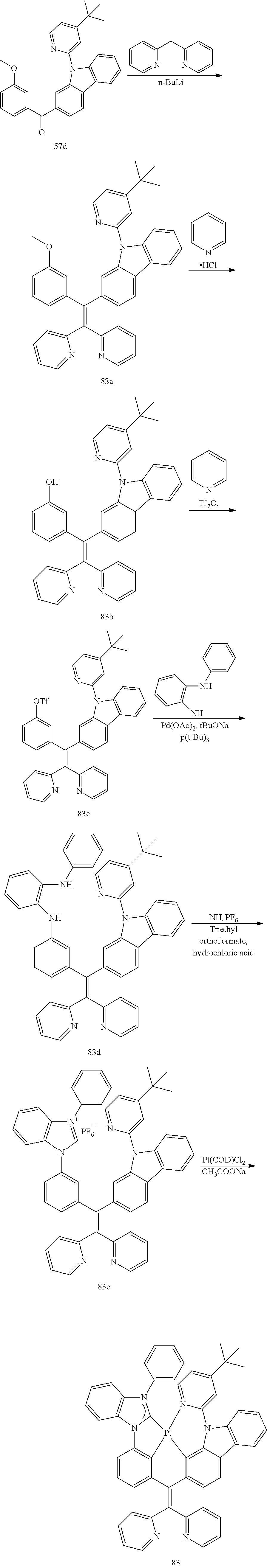

### Synthesis of Compound 83a

Under nitrogen protection, bis(2-pyridyl) methane (4.0 g, 23.5 mmol) was dissolved in tetrahydrofuran (150 mL) to obtain a solution, into which n-butyllithium (2 M, 10 mL) was added dropwise. The solution was stirred for reaction for 1 h, and then heated to −40° C. for further reaction for 0.5 h. Compound 57d (8.5 g, 19.6 mmol) and tetrahydrofuran (100 mL) were added dropwise to the above solution, and the reaction was continued overnight. After the reaction was completed, 200 mL of water were added thereto. The resulting solution was extracted with ethyl acetate (150 mL*3). The organic phase was removed by vacuum distillation under reduced pressure, and the resulting residue was subjected to silica gel column chromatography to obtain 7.2 g of light yellow solid with a yield rate of 62.7%. HRMS (ESI) (m/=): 587.2845 [M+H]⁺.

### Synthesis of Compound 83b

Under nitrogen protection, a mixture of compound 83a (6.0 g, 10.2 mmol) and pyridine hydrochloride (60 g) was heated to 190° C. for reaction for 6 h to obtain a solution. The solution was cooled to room temperature, into which 200 mL of water were added, and the solution was extracted with ethyl acetate (200 mL*3). The organic phase was removed by vacuum distillation under reduced pressure, and the resulting residue was subjected to silica gel column chromatography to obtain 5.5 g of light yellow solid with a yield rate of 93.9%. HRMS (ESI) (m/z): 572.2651 [M+H]⁺.

### Synthesis of Compound 83c

A 250 mL three-necked bottle was taken and added with 83b (5.0 g, 8.73 mmol), pyridine (1.38 g, 17.5 mmol) and dichloromethane (60 mL), into which trifluoromethanesulfonic anhydride (9.34 g, 33.1 mmol) was added dropwise in an ice bath under nitrogen protection. The resulting solution was heated to room temperature naturally and stirred overnight. After the reaction was completed, water (100 mL) was added to the solution, and the solution was extracted with dichloromethane (100 mL*3). The organic phase was removed by vacuum distillation under reduced pressure, and the resulting residue was subjected to silica gel column chromatography to obtain 5.2 g of light yellow solid with a yield rate of 84.5%. HRMS (ESI) (m/=): 705.2138 [M+H]⁺.

### Synthesis of Compound 83d

Under nitrogen protection, a mixture of 83c (5.0 g, 7.09 mmol), sodium tert-butoxide (1.02 g, 10.6 mmol), N-phenyl-o-phenylenediamine (1.56 g, 8.51 mmol), palladium acetate (0.16 g, 0.71 mmol), tri-tert-butylphosphine (0.14 g, 0.71 mmol) and toluene (500 mL) was heated to 120° C. and reacted overnight. After the reaction was completed, water (100 mL) was added thereto. The resulting solution was extracted with dichloromethane (100 mL*3). The organic phase was removed by vacuum distillation under reduced pressure, and the resulting residue was subjected to silica gel column chromatography to obtain 3.90 g of light yellow solid with a yield rate of 74.4%. HRMS (ESI) (m/z): 739.3567 [M+H]⁺.

### Synthesis of Compound 83e

Under nitrogen protection, a mixture of compound 83d (2.9 g, 3.92 mmol), triethyl orthoformate (20 mL), ammonium hexafluorophosphate (3.84 g, 23.6 mmol) and acid salt (0.2 mL) was heated to 80° C. and stirred for reaction for 24 h, and 1.8 g of product was obtained by filtration, with a yield rate of 61.2%. HRMS (ESI) (m/z): 749.3383 [M-PF6]⁺.

### Synthesis of Complex 83

Under nitrogen protection, compound 83e (800 mg, 1.07 mmol), Pt(COD)Cl₂ (379 mg, 1.28 mmol) and sodium acetate (263 mg, 3.2 mmol) were added to the tetrahydrofuran solution (20 mL) and reacted at 120° C. for 24 h. After the reaction was completed, water (100 mL) was added thereto. The resulting solution was extracted with dichloromethane (100 mL*3). The organic phase was removed by vacuum distillation under reduced pressure, and the resulting residue was subjected to silica gel column chromatography to obtain 0.28 g of light yellow solid with a yield rate of 27.7%. HRMS (ESI) (m/z): 942.2854 [M+H]⁺.

### Example 3: Preparation of Complex 84

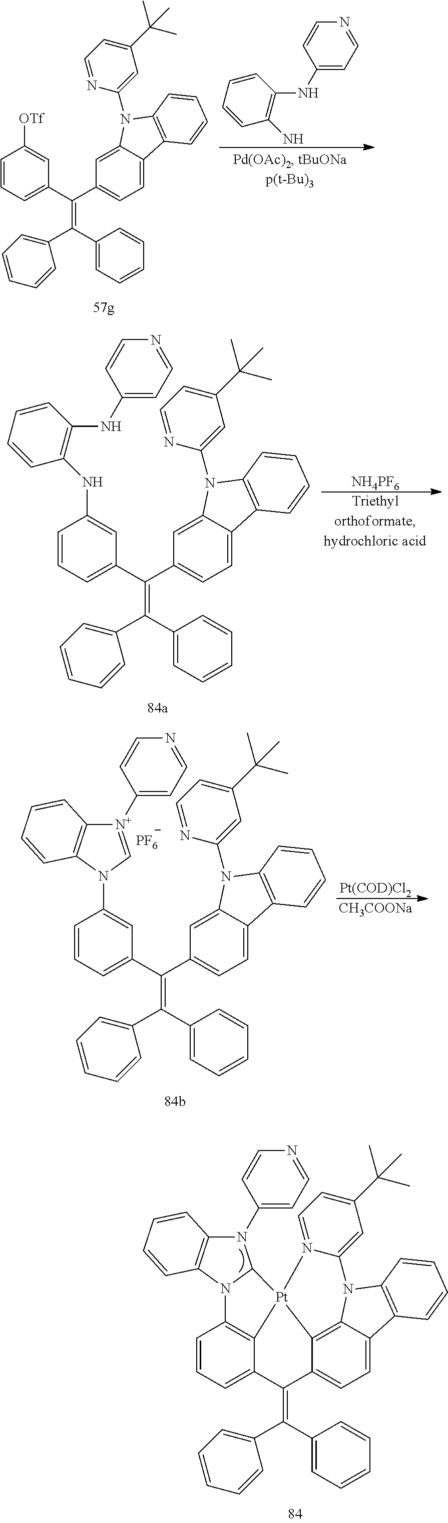

### Synthesis of Compound 84a

Under nitrogen protection, a mixture of 57g (2.1 g, 3.00 mmol), sodium tert-butoxide (0.43 g, 4.48 mmol), N-(4-pyridyl)-o-phenylenediamine (0.66 g, 3.59 mmol, see U.S. Pat. No. 4,855,308 for synthesis), palladium acetate (0.067 g, 0.30 mmol), tri-tert-butylphosphine (0.06 g, 0.30 mmol) and toluene (30 mL) was heated to 120° C. and reacted overnight. After the reaction was completed, water (100 mL) was added thereto. The resulting solution was extracted with dichloromethane (100 mL*3). The organic phase was removed by vacuum distillation under reduced pressure, and the resulting residue was subjected to silica gel column chromatography to obtain 1.50 g of light yellow solid with a yield rate of 68.0%. HRMS (ESI) (m/=): 738.3567 [M+H]⁺.

### Synthesis of Compound 84b

Under nitrogen protection, a mixture of compound 84b (1.4 g, 1.9 mmol), triethyl orthoformate (20 mL), ammonium hexafluorophosphate (1.86 g, 11.4 mmol) and acid salt (0.2 mL) was heated to 80° C. and stirred for reaction for 24 h, and 1.2 g of product was obtained by filtration, with a yield rate of 70.8%. HRMS (ESI) (m/z): 748.3436 [M-PF6]⁺.

### Synthesis of Complex 84

Under nitrogen protection, compound 84b (900 mg, 1.01 mmol), Pt(COD)Cl₂ (358 mg, 1.21 mmol) and sodium acetate (165 mg, 2.0 mmol) were added to the tetrahydrofuran solution (20 mL) and reacted at 120° C. for 24 h. After the reaction was completed, water (100 mL) was added thereto. The resulting solution was extracted with dichloromethane (100 mL*3). The organic phase was removed by vacuum distillation under reduced pressure, and the resulting residue was subjected to silica gel column chromatography to obtain 0.26 g of light yellow solid with a yield rate of 27.7%. HRMS (ESI) (m/=): 941.2930 [M+H]⁺.

### Examples 4-6

An organic light-emitting diode is prepared using the complex light-emitting material of the present disclosure. The device structure is shown in FIGURE.

First, a transparent conductive ITO glass substrate 10 (with an anode 20 thereon) was washed with a detergent solution and deionized water, ethanol, acetone, and deionized water successively, and then treated with oxygen plasma for 30 s.

Then, HATCN was evaporated on the ITO to prepare a hole injection layer 30.

Then, HT was evaporated on the hole injection layer to form a hole transport layer 40 with a thickness of 40 nm.

Then, a light-emitting layer 50 was evaporated on a hole blocking layer to form a light-emitting layer, and the light-emitting layer was composed of a platinum complex: BH (base material)=6%: 100% (the platinum complexes corresponding to Examples 4-6 were Complexes 57, 83, 84, respectively).

Then, ET having a thickness of 40 nm was evaporated on the light-emitting layer as an electron transport layer 60.

Finally, 1 nm LiF was evaporated as an electron injection layer 70 and 100 nm Al was used as a cathode 80 of the device.

### Comparative Example 1

The device of Comparative example 1 was prepared by the same preparation method, using a compound Ref-Pt instead of the platinum complexes in the above examples.

Structural formulas of HATCN, HT, BH, ET and Ref-Pt in the device are as follows:

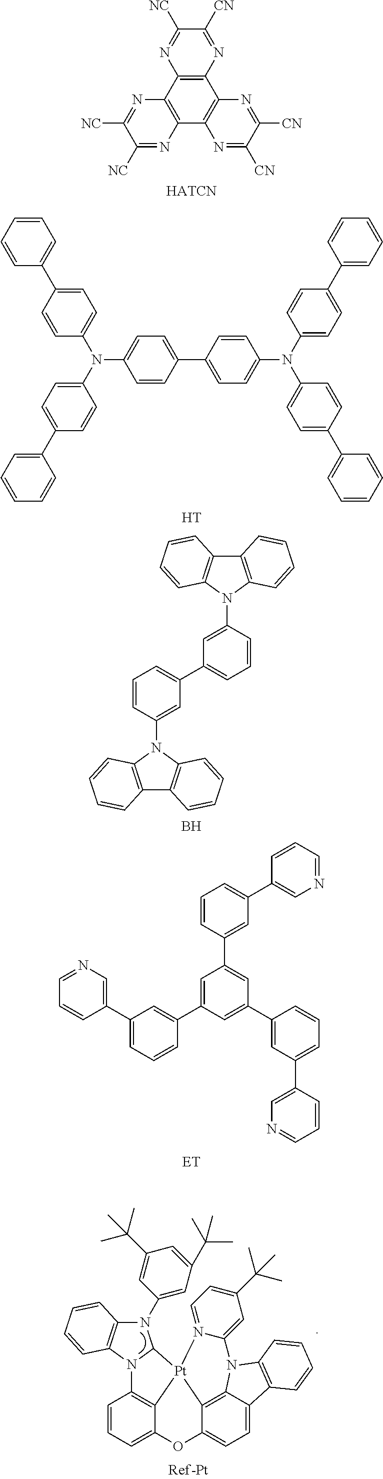

The device performance of the organic electroluminescent devices of Examples 4-6 and Comparative example 1 at a current density of 10 mA/cm² is listed in Table 1:

TABLE 1

| | | Driving | Luminous | Emitting | Device |
|---|---|---|---|---|---|
| Device No. | Complex | voltage | efficiency | color | life (LT90) |
| Comparative | Ref-Pt | 1 | 1 | blue | 1 |
| example 1 | | | | | |
| Example 4 | 57 | 0.98 | 1.25 | blue | 2.8 |
| Example 5 | 83 | 0.94 | 1.19 | blue | 1.6 |
| Example 6 | 84 | 0.96 | 1.15 | blue | 1.6 |

Remark: the device performance testing was based on Comparative example 1 with all indicators set to be 1; LT90 indicated the time corresponding to the device brightness decaying to 90% (initial brightness of 1000 cd/m²).

It can be seen from the data in Table 1 that under the same conditions, the platinum complex material of the present disclosure is used in organic light-emitting diodes, emitted deep red light, and had a higher luminous efficiency than the reference molecule Ref-Pt. It is worth noting that the device life of the organic light-emitting diode based on the complex of the present disclosure is significantly better than that of the complex material in the comparative example, and has good industrialization potential.

The various embodiments described above are only examples and are not intended to limit the scope of the present disclosure. Various materials and structures in the present disclosure can be replaced by other materials and structures without departing from the spirit of the present disclosure. It should be understood that those skilled in the art can make many modifications and changes according to the ideas of the present disclosure without creative efforts. Therefore, any technical solution that a skilled person can obtain through analysis, reasoning or partial research based on the existing technology should be within the scope of protection limited by the claims.

1. A tetradentate platinum complex, having a structure of formula (I): 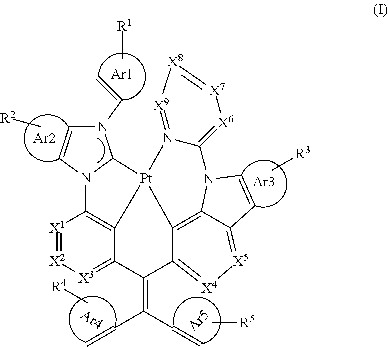
wherein:
X¹-X⁹ are independently selected from N or CR⁶;
R¹ to R⁶ are independently selected from hydrogen, deuterium, amine, halogen, carbonyl group, carboxyl group, cyano group, phosphino, substituted or unsubstituted alkyl group with 1-20 carbon atoms, substituted or unsubstituted cycloalkyl group with 3-20 ring carbon atoms, substituted or unsubstituted alkenyl group with 2-20 carbon atoms, substituted or unsubstituted alkoxy group with 1-20 carbon atoms, substituted or unsubstituted aryl group with 6-30 carbon atoms, or substituted or unsubstituted heteroaryl group with 3-30 carbon atoms;
Ar¹ to Ar⁵ are five-membered aromatic rings, six-membered aromatic rings, five-membered heteroaromatic rings or six-membered heteroaromatic rings;
a heteroatom in the heteroaryl group or the heteroaromatic ring is one or more of N, O and S; and
a substitution is conducted by halogen, amine, cyano group or C1-C4 alkyl group.

2. The platinum complex according to claim 1, wherein R¹ to R⁶ are each independently selected from hydrogen, deuterium, halogen, amine, cyano group, substituted or unsubstituted alkyl group with 1-6 carbon atoms, substituted or unsubstituted cycloalkyl group with 3-6 ring carbon atoms, substituted or unsubstituted alkenyl group with 2-6 carbon atoms, substituted or unsubstituted alkoxy group with 1-6 carbon atoms, substituted or unsubstituted aryl group with 6-12 carbon atoms, or substituted or unsubstituted of heteroaryl group with 3-6 carbon atoms.

3. The platinum complex according to claim 2, wherein R¹ to R⁶ are each independently selected from hydrogen, deuterium, halogen, C1-C4 alkyl, cyano group, substituted or unsubstituted cycloalkyl with 3-6 cyclic carbon atoms, substituted or unsubstituted aryl group with 6-12 carbon atoms, or substituted or unsubstituted heteroaryl group with 3-6 carbon atoms.

4. The platinum complex according to claim 3, wherein R¹ to R⁶ are each independently selected from hydrogen, deuterium, fluorine, methyl, isopropyl, isobutyl, tert-butyl, cyano group, substituted or unsubstituted cyclopentyl, substituted or unsubstituted cyclohexyl, substituted or unsubstituted phenyl, substituted or unsubstituted pyridyl, substituted or unsubstituted pyrazinyl, or substituted or unsubstituted pyrimidinyl.

5. The platinum complex according to claim 4, wherein the formula (I) is one of the following structures: 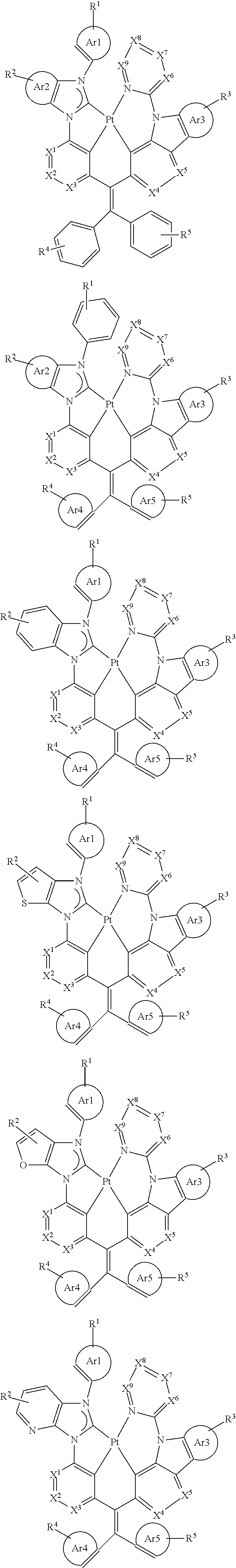 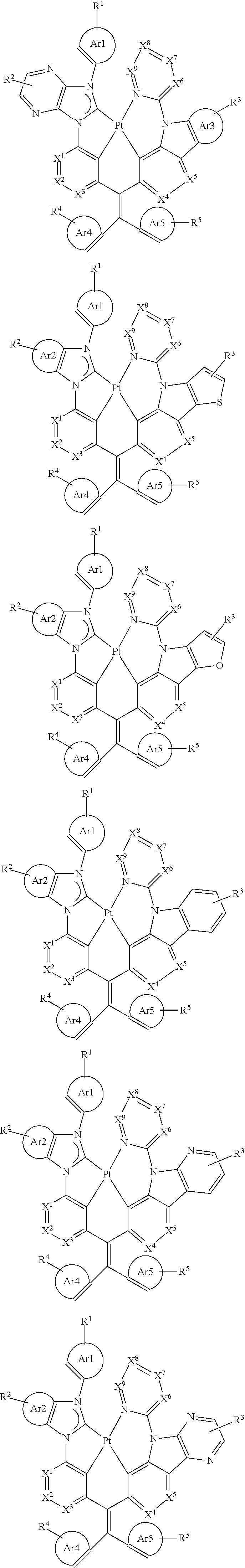
R¹ to R⁶ are each independently selected from hydrogen, deuterium, fluorine, methyl, tert-butyl, cyano group, substituted or unsubstituted cyclopentyl, substituted or unsubstituted cyclohexyl, or substituted or unsubstituted phenyl.

6. The platinum complex according to claim 5, wherein Ar¹, Ar⁴ and Ar⁵ are each independently selected from a five-membered aromatic ring, a six-membered aromatic ring, a five-membered heteroaromatic ring, and a six-membered heteroaromatic ring; and Ar¹ and Ar³ are each independently selected from a six-membered aromatic ring or a six-membered heteroaromatic ring.

7. The platinum complex according to claim 6, wherein the formula (I) is one of the following structures: 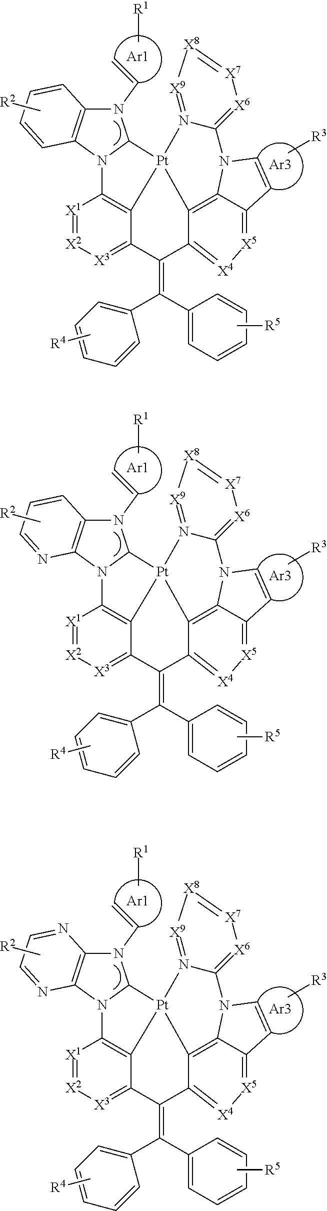
wherein X¹-X³ and X⁶-X⁹ are independently selected from CR⁶; and X⁴-X⁵ are independently selected from N or CR⁶.

8. The platinum complex according to claim 6, wherein Ar¹, Ar⁴ and Ar⁵ are selected from phenyl or pyridyl; Ar² and Ar³ are each independently selected from a six-membered aromatic ring; and X¹-X³, X⁶-X⁹ and X⁴-X⁵ are independently selected from CR⁶.

9. The platinum complex according to claim 8, wherein R¹ to R⁶ are each independently selected from hydrogen, deuterium, fluorine, or tert-butyl.

10. The platinum complex according to claim 1, selected from one of the following compounds:

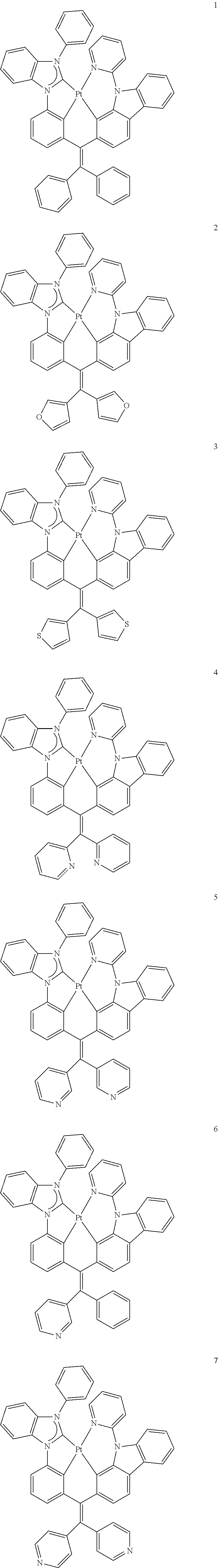

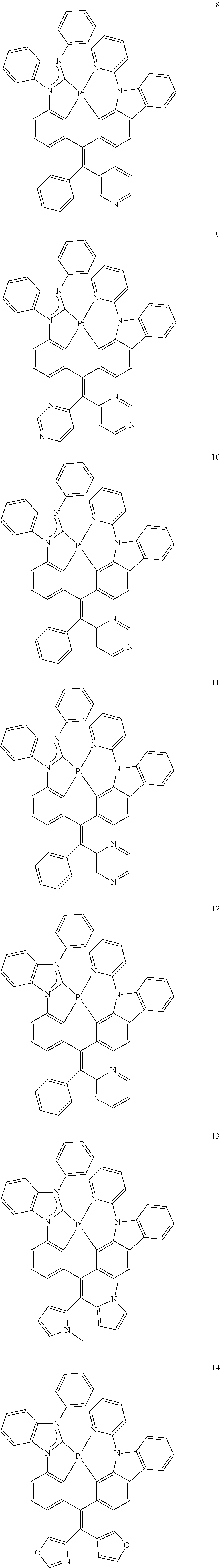

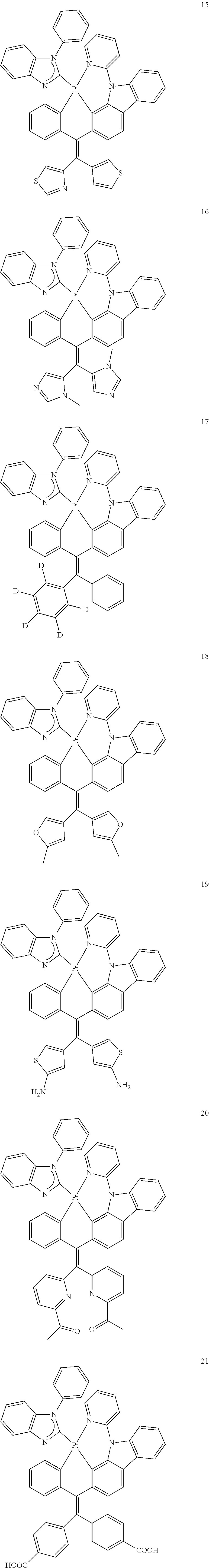

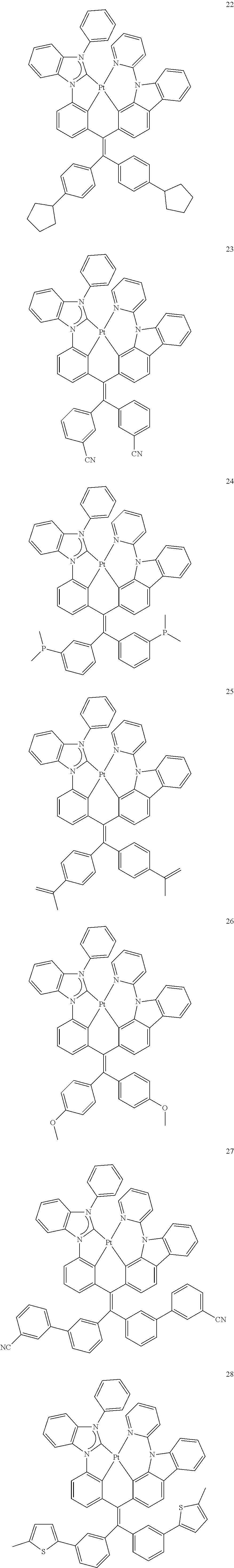

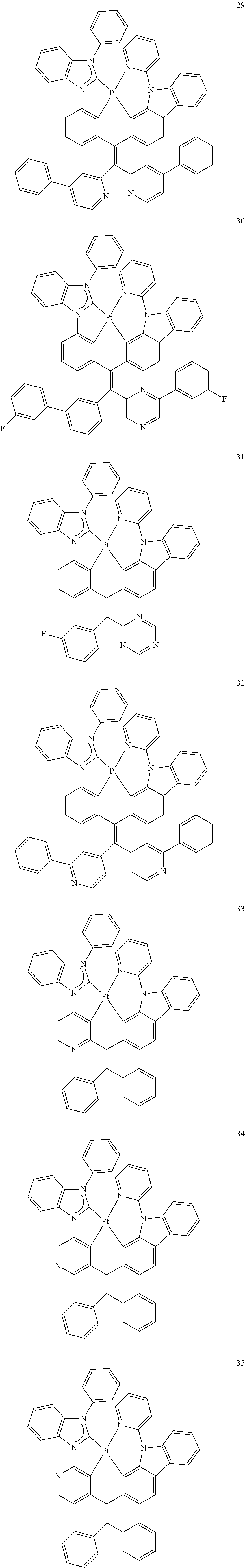

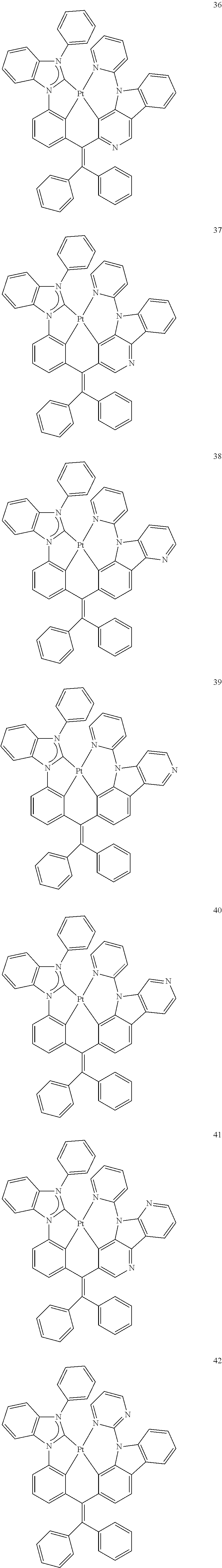

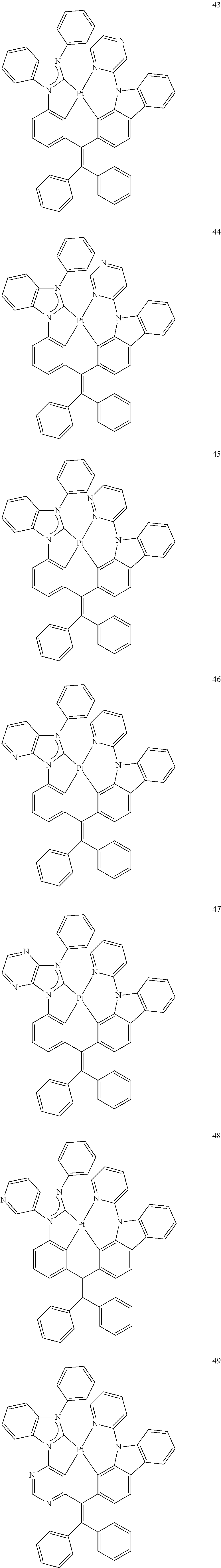

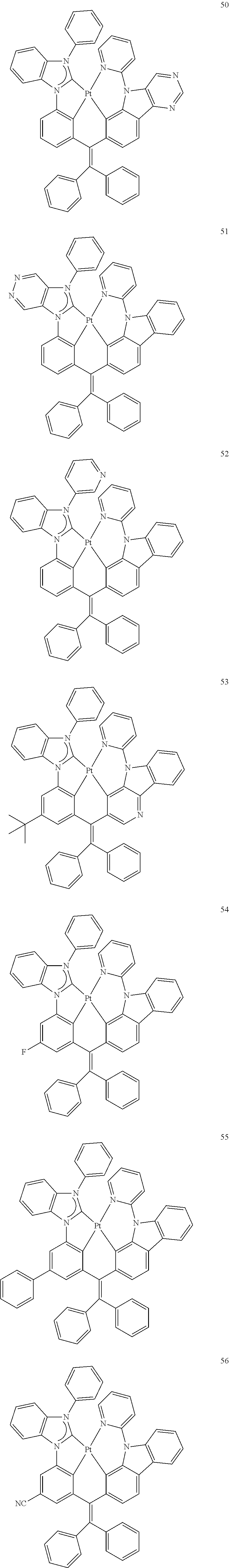

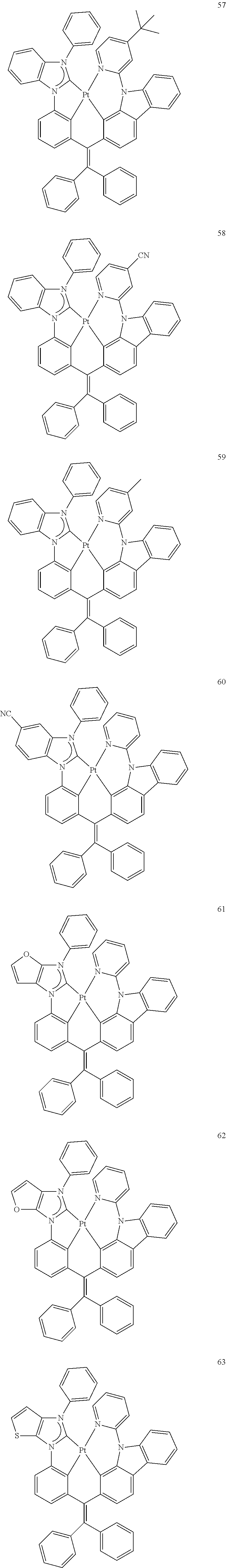

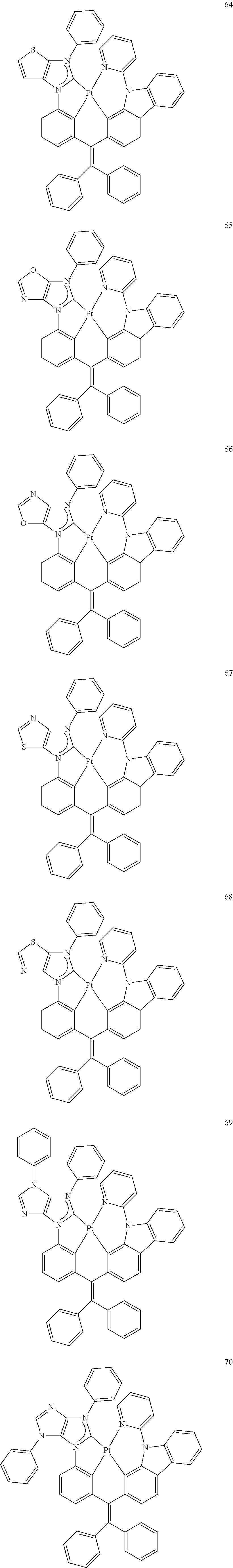

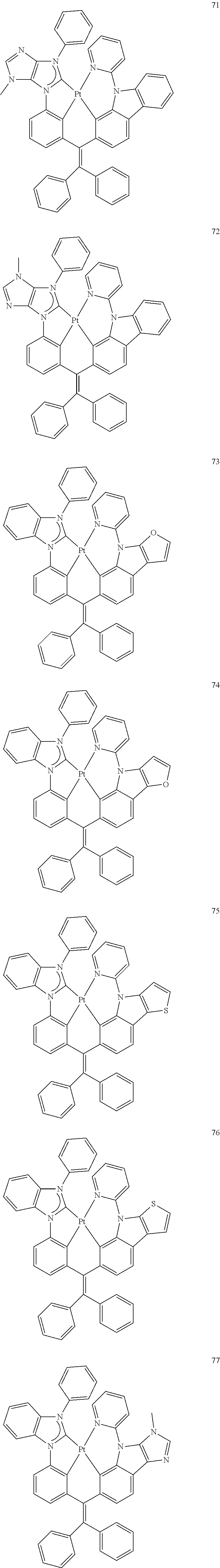

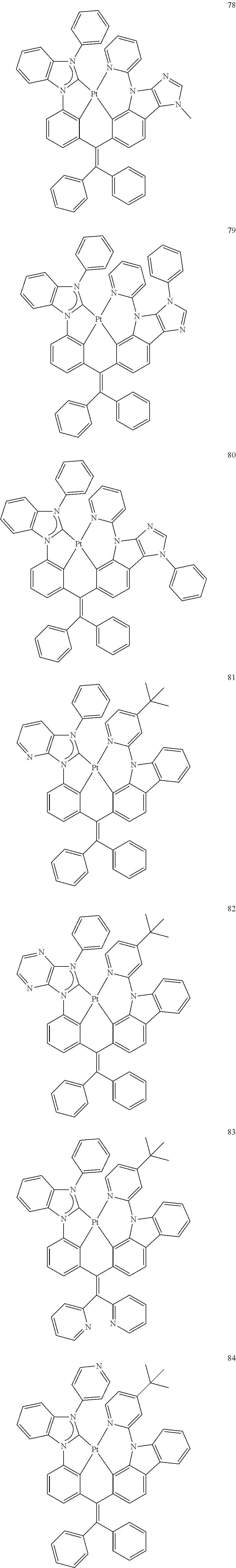

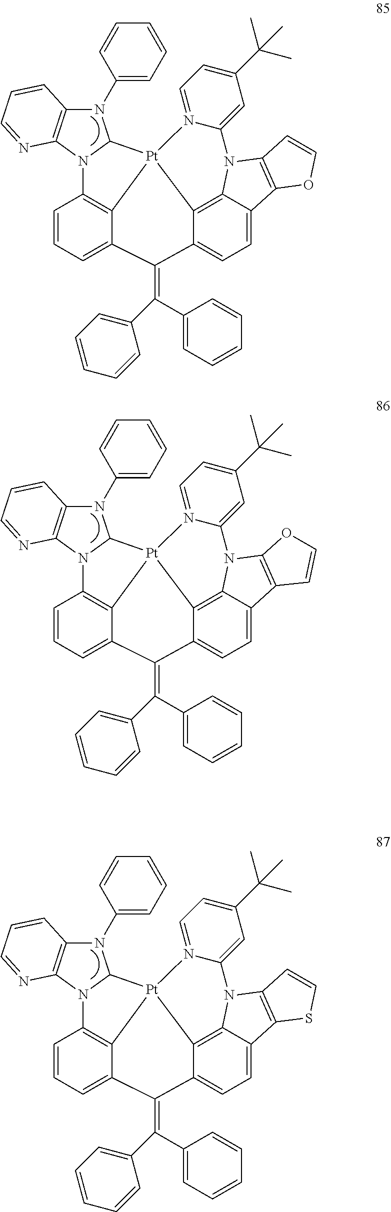

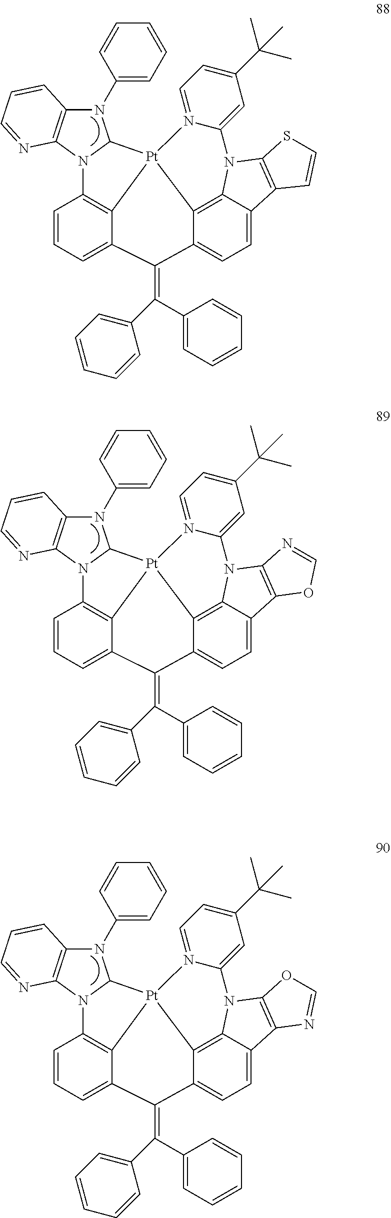

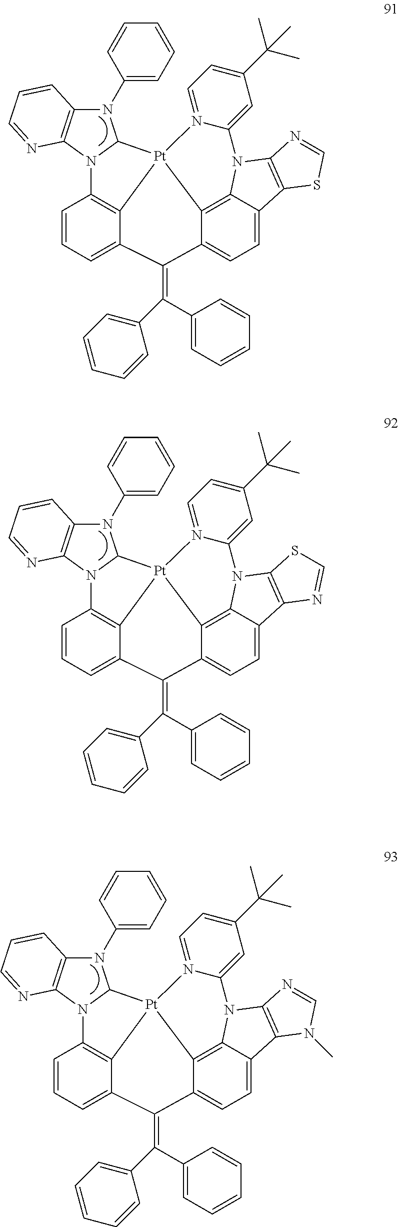

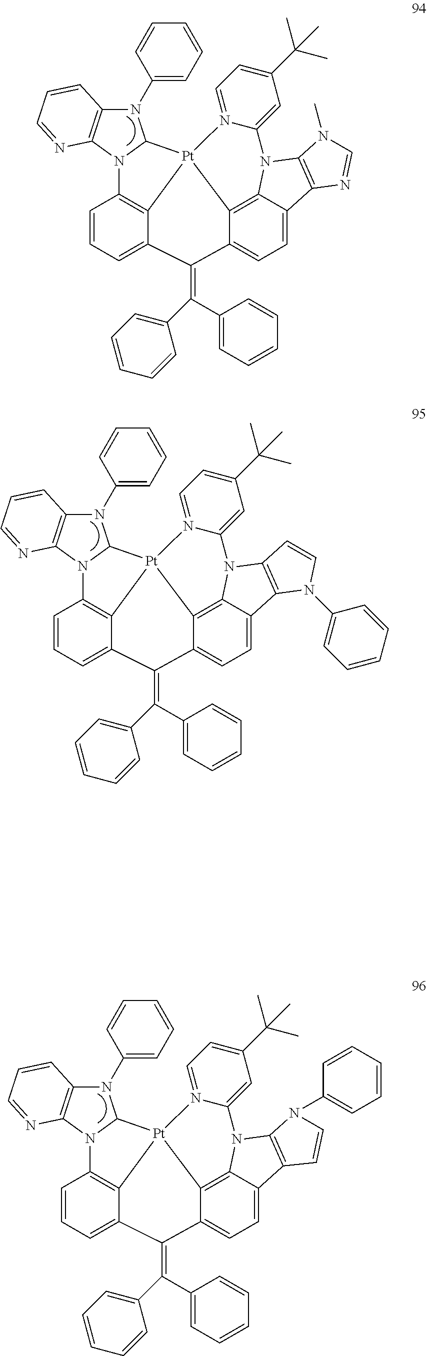

11. A precursor of the platinum complex according to claim 1, wherein the precursor has a structural formula as follows: 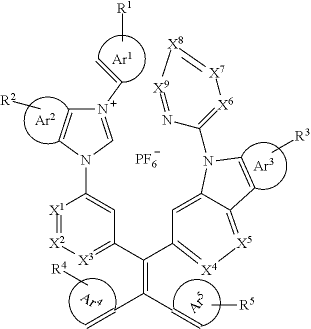
wherein X¹-X⁹, R¹ to R³, and Ar¹ to Ar⁵ are defined as formula (I).

12. An organic optoelectronic device comprising the platinum complex according to claim 1, wherein the organic optoelectronic device is an organic light-emitting diode, an organic thin film transistor, an organic photovoltaic device, a light-emitting electrochemical cells or a chemical sensor.

13. An organic light-emitting diode, comprising a cathode, an anode and an organic layer, wherein the organic layer is one or more of a hole injection layer, a hole transport layer, a light-emitting layer, a hole blocking layer, an electron injection layer and an electron transport layer, and wherein the organic layer contains the platinum complex according to claim 1.

14. The organic light-emitting diode according to claim 10, wherein the layer in which the platinum complex is located is the light-emitting layer.

15. The platinum complex according to claim 7, wherein Ar¹, Ar⁴ and Ar⁵ are selected from phenyl or pyridyl; Ar² and Ar³ are each independently selected from a six-membered aromatic ring; and X¹-X³, X⁶-X⁹ and X⁴-X⁵ are independently selected from CR⁶.
